(19) United States
(12) Patent Application Publication
(10) Pub. No.: US 2025/0374611 A1
(43) Pub. Date: Dec. 4, 2025

(54) PROTECTIVE HARD MASK AND METHODS OF MAKING SAME

(71) Applicant: Taiwan Semiconductor Manufacturing Co., Ltd., Hsinchu (TW)

(72) Inventors: Sih-Jie Liu, Hsinchu (TW); Min-Tsang Li, Hsinchu (TW); Bau-Ming Wang, Kaohsiung (TW); Po-Kang Ho, Taoyuan (TW); Chu-Yen Hsiao, Taoyuan (TW)

(21) Appl. No.: 18/829,955

(22) Filed: Sep. 10, 2024

Related U.S. Application Data
(60) Provisional application No. 63/655,661, filed on Jun. 4, 2024.

(51) Int. Cl. H01L 29/786; H01L 21/311; H01L 21/768; H01L 29/06; H01L 29/66; H01L 29/775

(52) U.S. Cl. CPC H10D 30/6757; H01L 21/31144; H01L 21/76825; H01L 21/76828; H10D 30/014; H10D 30/43; H10D 62/121; H10D 64/017

(57) ABSTRACT

A method includes depositing a first interlayer dielectric (ILD) surrounding a first dummy gate stack and a second dummy gate stack; recessing the first ILD below top surfaces of the first dummy gate stack and the second dummy gate stack; forming a hard mask over the first ILD and between the first dummy gate stack and the second dummy gate stack; performing an ion implantation process to implant dopants into the hard mask, wherein the ion implantation process reduces an etch rate of the hard mask to an oxide etch process; and after performing the ion implantation process, replacing the first dummy gate stack and the second dummy gate stack with a first gate stack and a second gate stack.

### PRIORITY CLAIM

This application claims priority to U.S. Provisional Application No. 63/655,661, filed on Jun. 4, 2024, which application is hereby incorporated by reference.

### BACKGROUND

Semiconductor devices are used in a variety of electronic applications, such as, for example, personal computers, cell phones, digital cameras, and other electronic equipment. Semiconductor devices are typically fabricated by sequentially depositing insulating or dielectric layers, conductive layers, and semiconductor layers of material over a semiconductor substrate, and patterning the various material layers using lithography to form circuit components and elements thereon.

The semiconductor industry continues to improve the integration density of various electronic components (e.g., transistors, diodes, resistors, capacitors, etc.) by continual reductions in minimum feature size, which allow more components to be integrated into a given area. However, as the minimum features sizes are reduced, additional problems arise that should be addressed.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIG. 1 illustrates an example of a nanostructure field-effect transistor (nano-FET) in a three-dimensional view, in accordance with some embodiments.

FIGS. 2, 3, 4, 5A, 5B, 6A, 6B, 7A, 7B, 7C, 8A, 8B, 9A, 9B, 10A, 10B, 10C, 10D, 11A, 11B, 11C, 11D, 12A, 12B, 13A, 13B, 14A, 14B, 14C, 15A, 15B, 15C, 15D, 15E, 15F, 16A, 16B, 17A, 17B, 18A, 18B, 18C, 19A, 19B, 19C, 20A, 20B, 21A, 21B, and 21C illustrate varying views of intermediary steps of manufacturing a nano-FET transistor, in accordance with some embodiments.

FIGS. 22A, 22B, 23A, 23B, 24A, 24B, 25A, 25B, 26A, 26B, 27A, 27B, 28A, 28B, and 28C illustrate varying views of intermediary steps of manufacturing a nano-FET transistor, in accordance with some embodiments.

### DETAILED DESCRIPTION

The following disclosure provides many different embodiments, or examples, for implementing different features of the invention. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

In various embodiments, a hard mask is formed over an interlayer dielectric (ILD) that is deposited between gate stacks and that covers source/drain regions of transistor devices. The hard mask protects the ILD from etching during subsequent processing steps of forming the transistor devices. The ILD may be an oxide material that is susceptible to one or more oxide etching processes used to form the transistor devices. Damage to the ILD may result in damage (e.g., inadvertent etching) of the underlying source/drain regions, resulting in poor device performance. In various embodiments, an effectiveness of the hard mask can be increased by performing an ion implantation and annealing process on the hard mask. The ion implantation and annealing process may increase the effectiveness of the hard mask in one or more of the following, non-limiting manners. First, the ion implantation and annealing process may improve adhesion between the hard mask and surrounding features (e.g., gate spacers) by expanding the hard mask. Second, the ion implantation and annealing process may reduce the etching rate of the hard mask and the ILD during oxide etching processes. Third, the ion implantation and annealing process may increase a density of the hard mask and the ILD through impurity reduction. As a result, the quality and effectiveness of the hard mask can be improved, and manufacturing defects (e.g., damage to the ILD and/or source/drain regions) may be reduced.

Embodiments are described below in a particular context, a die comprising nano-FETs. Various embodiments may be applied, however, to dies comprising other types of transistors (e.g., stacking transistors, or the like) in lieu of or in combination with the nano-FETs.

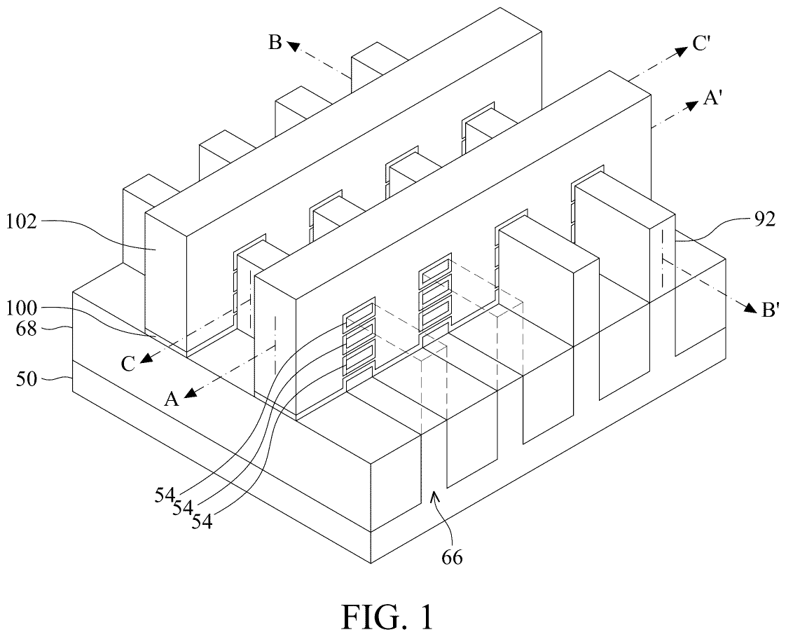

FIG. 1 illustrates an example of nano-FETs (e.g., nanowire FETs, nanosheet FETs, or the like) in a three-dimensional view, in accordance with some embodiments. Certain features are simplified and/or omitted in FIG. 1 for ease of illustration. The nano-FETs comprise nanostructures 54 (e.g., nanosheets, nanowires, or the like) over fins 66 on a substrate 50 (e.g., a semiconductor substrate), wherein the nanostructures 54 act as channel regions for the nano-FETs. The nanostructure 54 may include p-type nanostructures, n-type nanostructures, or a combination thereof. Shallow trench isolation (STI) regions 68 (also referred to as STI structures or STI regions) are disposed between adjacent fins 66, which may protrude above and from between neighboring STI regions 68. Although the STI regions 68 are described/illustrated as being separate from the substrate 50, as used herein, the term “substrate” may refer to the semiconductor substrate alone or a combination of the semiconductor substrate and the isolation regions. Additionally, although a bottom portion of the fins 66 are illustrated as being single, continuous materials with the substrate 50, the bottom portion of the fins 66 and/or the substrate 50 may comprise a single material or a plurality of materials. In this context, the fins 66 refer to the portion extending between the neighboring STI regions 68.

Gate dielectric layers 100 are over top surfaces of the fins 66 and along top surfaces, sidewalls, and bottom surfaces of the nanostructures 54. Gate electrodes 102 are over the gate dielectric layers 100. Epitaxial source/drain regions 92 are disposed on the fins 66 on opposing sides of the gate dielectric layers 100 and the gate electrodes 102. Source/drain region(s) 92 may refer to a source or a drain, individually or collectively dependent upon the context.

FIG. 1 further illustrates reference cross-sections that are used in later figures. Cross-section A-A′ is along a longitudinal axis of a gate electrode 102 and in a direction, for example, perpendicular to the direction of current flow between the epitaxial source/drain regions 92 of a nano-FET. Cross-section B-B′ is perpendicular to cross-section A-A′ and is parallel to a longitudinal axis of a fin 66 of the nano-FET and in a direction of, for example, a current flow between the epitaxial source/drain regions 92 of the nano-FET. Cross-section C-C′ is parallel to cross-section A-A′ and extends through epitaxial source/drain regions of the nano-FETs. Subsequent figures refer to these reference cross-sections for clarity.

Some embodiments discussed herein are discussed in the context of nano-FETs formed using a gate-last process. In other embodiments, a gate-first process may be used. Also, some embodiments contemplate aspects used in planar devices, such as planar FETs or in fin field-effect transistors (FinFETs).

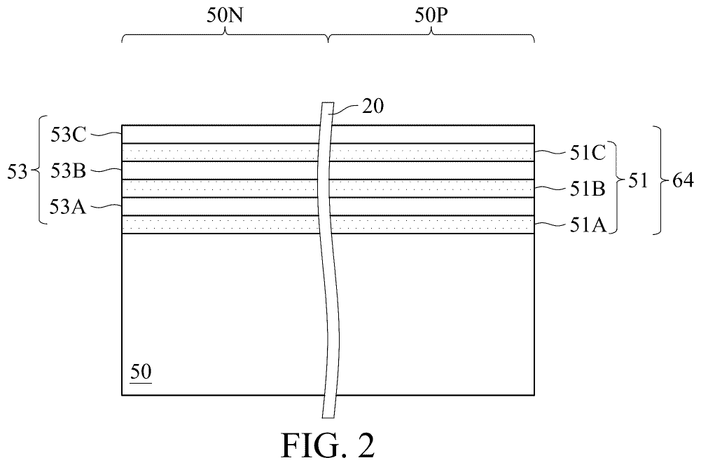

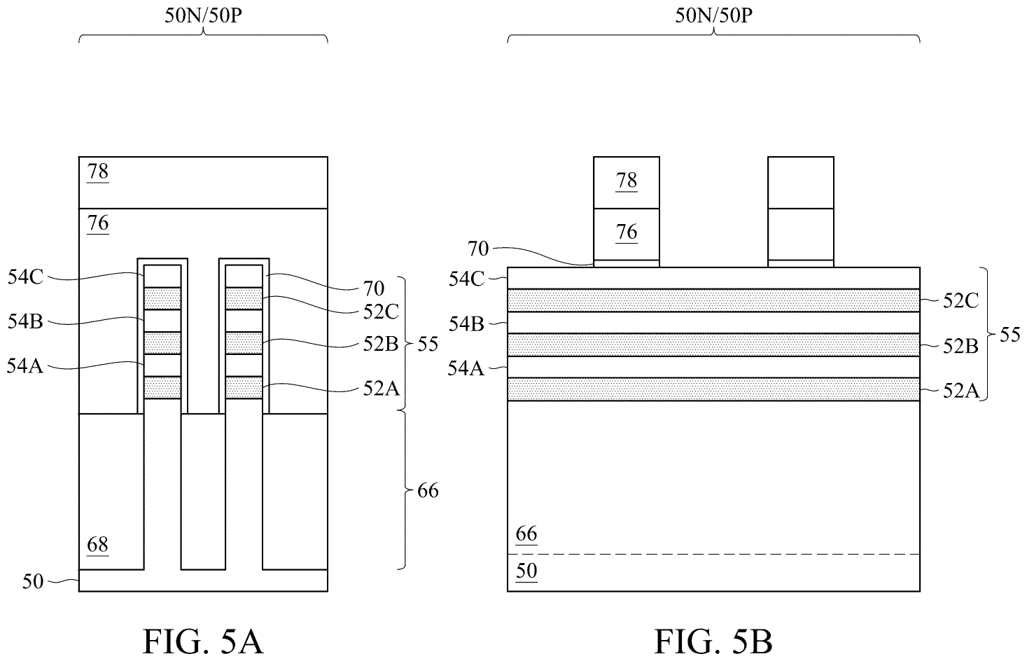

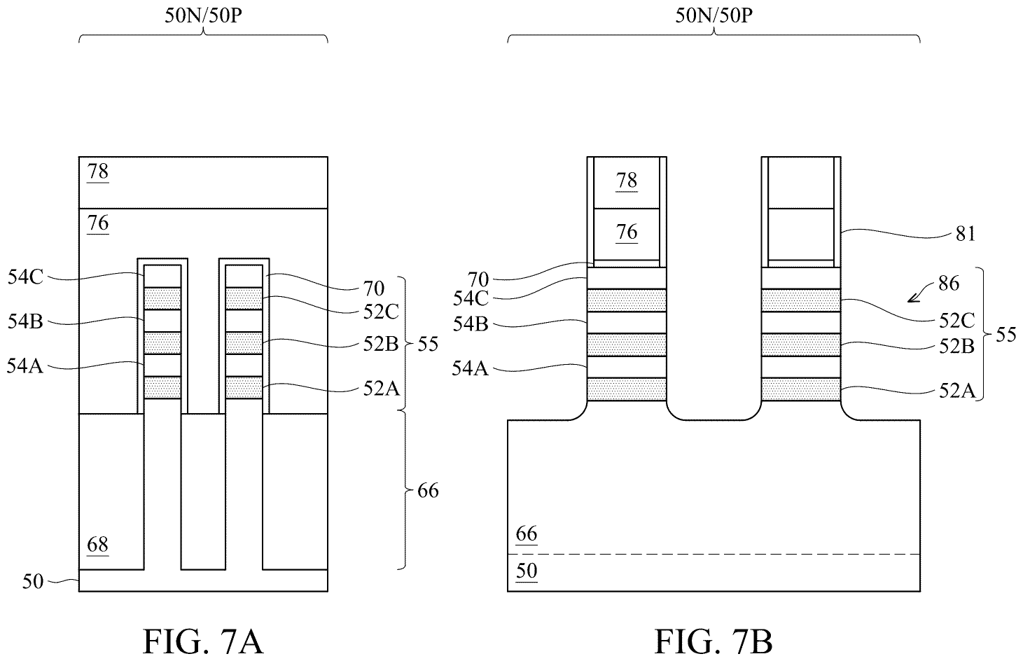

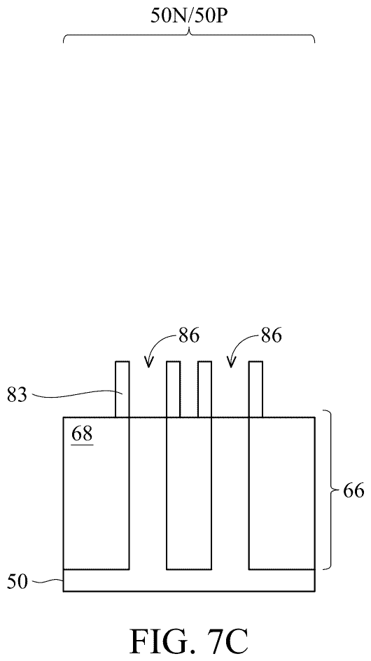

FIGS. 2 through 21C are cross-sectional views of intermediate stages in the manufacturing of nano-FETs, in accordance with some embodiments. FIGS. 2, 3, 4, 5A, 6A, 7A, 8A, 9A, 10A, 11A, 12A, 13A, 14A, 15A, 16A, 17A, 18A, 19A, 20A, and 21A illustrate reference cross-section A-A′ illustrated in FIG. 1. FIGS. 5B, 6B, 7B, 8B, 9B, 10B, 10C, 10D, 11B, 12B, 13B, 14B, 14C, 15B, 15C, 16B, 17B, 18B, 18C, 19B, 20B, and 21B illustrate reference cross-section B-B′ illustrated in FIG. 1. FIGS. 7C, 11C, 11D, 19C, and 21C illustrate reference cross-section C-C′ illustrated in FIG. 1.

In FIG. 2, a substrate 50 is provided. The substrate 50 may be a semiconductor substrate, such as a bulk semiconductor, a semiconductor-on-insulator (SOI) substrate, or the like, which may be doped (e.g., with a p-type or an n-type dopant) or undoped. The substrate 50 may be a wafer, such as a silicon wafer. Generally, an SOI substrate is a layer of a semiconductor material formed on an insulator layer. The insulator layer may be, for example, a buried oxide (BOX) layer, a silicon oxide layer, or the like. The insulator layer is provided on a substrate, typically a silicon or glass substrate. Other substrates, such as a multi-layered or gradient substrate may also be used. In some embodiments, the semiconductor material of the substrate 50 may include silicon; germanium; a compound semiconductor including silicon carbide, gallium arsenide, gallium phosphide, indium phosphide, indium arsenide, and/or indium antimonide; an alloy semiconductor including silicon-germanium, gallium arsenide phosphide, aluminum indium arsenide, aluminum gallium arsenide, gallium indium arsenide, gallium indium phosphide, and/or gallium indium arsenide phosphide; or combinations thereof.

The substrate 50 has an n-type region 50N and a p-type region 50P. The n-type region 50N can be for forming n-type devices, such as NMOS transistors, e.g., n-type nano-FETs, and the p-type region 50P can be for forming p-type devices, such as PMOS transistors, e.g., p-type nano-FETs. The n-type region 50N may be physically separated from the p-type region 50P (as illustrated by divider 20), and any number of device features (e.g., other active devices, doped regions, isolation structures, etc.) may be disposed between the n-type region 50N and the p-type region 50P. Although one n-type region 50N and one p-type region 50P are illustrated, any number of n-type regions 50N and p-type regions 50P may be provided. Subsequent figures describe processing steps that may be performed in either the n-type regions 50N or the p-type regions 50P unless otherwise noted.

Further in FIG. 2, a multi-layer stack 64 is formed over the substrate 50. The multi-layer stack 64 includes alternating layers of first semiconductor layers 51A-C (collectively referred to as first semiconductor layers 51) and second semiconductor layers 53A-C (collectively referred to as second semiconductor layers 53). For purposes of illustration and as discussed in greater detail below, the first semiconductor layers 51 will be removed and the second semiconductor layers 53 will be patterned to form channel regions of nano-FETs in both the n-type region 50N and the p-type region 50P. Nevertheless, in some embodiments, the second semiconductor layers 53 may be removed and the first semiconductor layers 51 may be patterned to form channel regions of nano-FETs in both the n-type region 50N and the p-type region 50P. For example, the channel regions in both the n-type region 50N and the p-type region 50P may have a same material composition (e.g., silicon, or another semiconductor material) and be formed simultaneously.

In other embodiments, the first semiconductor layers 51 may be removed and the second semiconductor layers 53 may be patterned to form channel regions of nano-FETs in the p-type region 50P, and the second semiconductor layers 53 may be removed and the first semiconductor layers 51 may be patterned to form channel regions of nano-FETs in the n-type region 50N. In still other embodiments, the first semiconductor layers 51 may be removed and the second semiconductor layers 53 may be patterned to form channel regions of nano-FETs in the n-type region 50N, and the second semiconductor layers 53 may be removed and the first semiconductor layers 51 may be patterned to form channel regions of nano-FETs in the p-type region 50P. In such embodiments, the channel regions of the n-type region 50N may have a different material composition than the channel regions of the p-type region 50P. The first semiconductor layers 51 and the second semiconductor layers 53 may be selectively removed from each of the n-type region 50N and p-type region 50P through additional masking and etching steps. For example, the channel regions of the n-type region 50N may be silicon channel regions while the channel regions of the p-type region 50P may be silicon germanium channel regions.

The multi-layer stack 64 is illustrated as including three layers of each of the first semiconductor layers 51 and the second semiconductor layers 53 for illustrative purposes. In some embodiments, the multi-layer stack 64 may include any number of the first semiconductor layers 51 and the second semiconductor layers 53. Each of the layers of the multi-layer stack 64 may be epitaxially grown using a process such as chemical vapor deposition (CVD), atomic layer deposition (ALD), vapor phase epitaxy (VPE), molecular beam epitaxy (MBE), or the like.

In various embodiments, the first semiconductor layers 51 may be formed of a first semiconductor material, such as silicon germanium, or the like, and the second semiconductor layers 53 may be formed of a second semiconductor material, such as silicon, silicon carbon, or the like. The first semiconductor materials and the second semiconductor materials may be materials having a high-etch selectivity to one another. As such, the first semiconductor layers 51 of the first semiconductor material may be removed without significantly removing the second semiconductor layers 53 of the second semiconductor material, thereby allowing the second semiconductor layers 53 to be patterned to form channel regions of the nano-FETs.

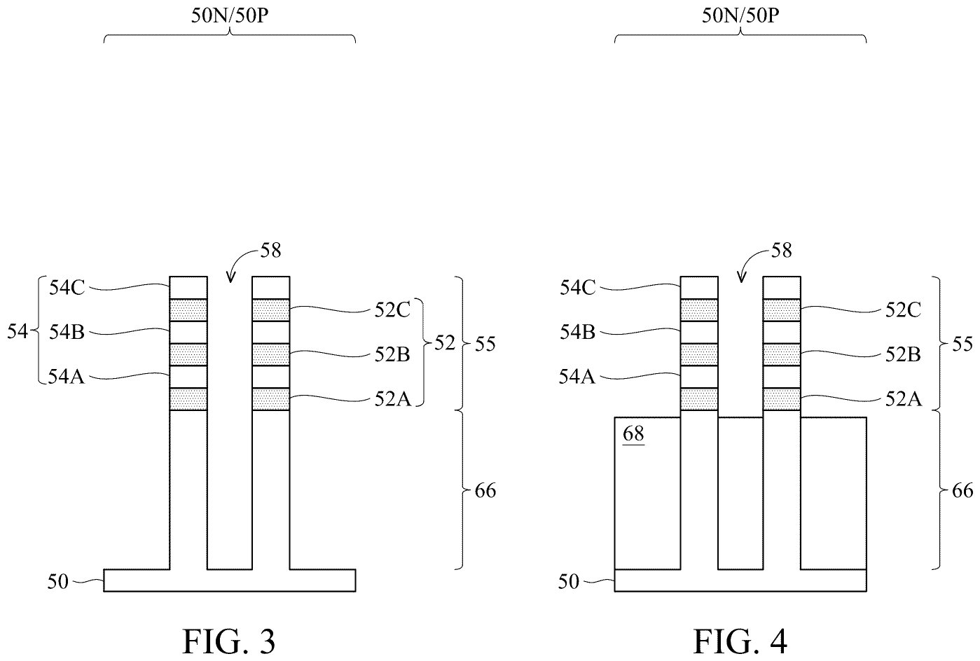

Referring now to FIG. 3, fins 66 are formed in the substrate 50 and nanostructures 55 are formed in the multi-layer stack 64, in accordance with some embodiments. In some embodiments, the nanostructures 55 and the fins 66 may be formed in the multi-layer stack 64 and the substrate 50, respectively, by etching trenches 58 in the multi-layer stack 64 and the substrate 50. The etching may be any acceptable etch process, such as a reactive ion etch (RIE), neutral beam etch (NBE), the like, or a combination thereof. The etching may be anisotropic. During the etching process, a hard mask may be used to define a pattern of the fins 66 and the nanostructures 55. The hard mask may comprise any suitable insulating material, such as an oxide, a nitride, and oxynitride, and oxycarbonitride, or the like. In some embodiments (not separately illustrated), the hard mask may be a multi-layer structure. The hard mask may be formed over the nanostructures 55 using an acceptable process(es) such as thermal oxidation, physical vapor deposition (PVD), CVD, ALD, combinations thereof, or the like.

The fins 66 and the nanostructures 55 may be patterned by any suitable method. For example, the fins 66 and the nanostructures 55 may be patterned using one or more photolithography processes, including double-patterning or multi-patterning processes. Generally, double-patterning or multi-patterning processes combine photolithography and self-aligned processes, allowing patterns to be created that have, for example, pitches smaller than what is otherwise obtainable using a single, direct photolithography process. For example, a sacrificial layer is formed over a substrate and patterned using a photolithography process. Spacers are then formed alongside the patterned sacrificial layer using a self-aligned process. The sacrificial layer is then removed, and the remaining spacers may then be used to pattern the fins 66 and the nanostructures 55.

Forming the nanostructures 55 by etching the multi-layer stack 64 may further define first nanostructures 52A-C (collectively referred to as the first nanostructures 52) from the first semiconductor layers 51 and define second nanostructures 54A-C (collectively referred to as the second nanostructures 54) from the second semiconductor layers 53. The first nanostructures 52 and the second nanostructures 54 may further be collectively referred to as the nanostructures 55.

FIG. 3 illustrates the fins 66 having substantially equal widths for illustrative purposes. In some embodiments, widths of the fins 66 in the n-type region 50N may be greater or thinner than the fins 66 in the p-type region 50P. Further, while FIG. 3 illustrates each of the fins 66 and the nanostructures 55 as having a consistent width throughout, in other embodiments, the fins 66 and/or the nanostructures 55 may have tapered sidewalls such that a width of each of the fins 66 and/or the nanostructures 55 continuously increases in a direction towards the substrate 50. In such embodiments, each of the nanostructures 55 may have a different width and be trapezoidal in shape.

In FIG. 4, shallow trench isolation (STI) regions 68 are formed adjacent the fins 66. The STI regions 68 may be formed by depositing an insulation material over the substrate 50, the fins 66, and nanostructures 55, and between adjacent fins 66 to fill the trenches 58. The insulation material may be an oxide, such as silicon oxide, a nitride, the like, or a combination thereof, and may be formed by high-density plasma CVD (HDP-CVD), flowable CVD (FCVD), the like, or a combination thereof. Other insulation materials formed by any acceptable process may be used. In the illustrated embodiment, the insulation material is silicon oxide formed by an FCVD process. An anneal process may be performed once the insulation material is formed. In an embodiment, the insulation material is formed such that excess insulation material covers the nanostructures 55. Although the insulation material is illustrated as a single layer, some embodiments may utilize multiple layers. For example, in some embodiments a liner (not separately illustrated) may first be formed along a surface of the substrate 50, the fins 66, and the nanostructures 55. Thereafter, a fill material, such as those discussed above may be formed over the liner.

A removal process is then applied to the insulation material to remove excess insulation material over the nanostructures 55. In some embodiments, a planarization process such as a chemical mechanical polish (CMP), an etch-back process, combinations thereof, or the like may be utilized. The planarization process exposes the nanostructures 55 such that top surfaces of the nanostructures 55 and the insulation material are level after the planarization process is complete.

The insulation material is then recessed to form the STI regions 68. The insulation material is recessed such that upper portions of fins 66 protrude from between neighboring STI regions 68. Further, the top surfaces of the STI regions 68 may be flat surfaces as illustrated, convex surfaces, concave surfaces (such as dishing), or a combination thereof. The top surfaces of the STI regions 68 may be formed flat, convex, and/or concave by an appropriate etch. The STI regions 68 may be recessed using an acceptable etching process, such as one that is selective to the material of the insulation material (e.g., etches the material of the insulation material at a faster rate than the material of the fins 66 and the nanostructures 55). For example, an oxide removal using, for example, dilute hydrofluoric (dHF) acid may be used. Thereafter, an optional hard mask (not separately illustrated) may then be formed over the top surfaces of the STI regions 68 to cover the STI regions 68. The hard mask may be made of a nitride or other material that has etch selectivity to the STI regions 68 (e.g., etch selectivity to a fill material of the STI regions 68).

Further in FIG. 4, appropriate wells (not separately illustrated) may be formed in the fins 66 and/or the nanostructures 55. In embodiments with different well types, different implant steps for the n-type region 50N and the p-type region 50P may be achieved using a photoresist or other masks (not separately illustrated). For example, a photoresist may be formed over the fins 66 and the nanostructures 55 in the n-type region 50N and the p-type region 50P. The photoresist is patterned to expose the p-type region 50P. The photoresist can be formed by using a spin-on technique and can be patterned using acceptable photolithography techniques. Once the photoresist is patterned, an n-type impurity implant is performed in the p-type region 50P, and the photoresist may act as a mask to substantially prevent n-type impurities from being implanted into the n-type region 50N. The n-type impurities may be phosphorus, arsenic, antimony, or the like implanted in the region to a concentration in a range from about 10¹³ atoms/cm³ to about 10¹⁴ atoms/cm³. After the implant, the photoresist is removed, such as by an acceptable ashing process.

Following or prior to the implanting of the p-type region 50P, a photoresist or other masks (not separately illustrated) is formed over the fins 66 and the nanostructures 55 in the p-type region 50P and the n-type region 50N. The photoresist is patterned to expose the n-type region 50N. The photoresist can be formed by using a spin-on technique and can be patterned using acceptable photolithography techniques. Once the photoresist is patterned, a p-type impurity implant may be performed in the n-type region 50N, and the photoresist may act as a mask to substantially prevent p-type impurities from being implanted into the p-type region 50P. The p-type impurities may be boron, boron fluoride, indium, or the like implanted in the region to a concentration in a range from about 10¹³ atoms/cm³ to about 10¹⁴ atoms/cm³. After the implant, the photoresist may be removed, such as by an acceptable ashing process.

After the implants of the n-type region 50N and the p-type region 50P, an anneal may be performed to repair implant damage and to activate the p-type and/or n-type impurities that were implanted. In some embodiments, the grown materials of epitaxial fins may be in situ doped during growth, which may obviate the implantations, although in situ and implantation doping may be used together.

In FIGS. 5A and 5B, dummy gates 76 are formed over and along sidewalls of the nanostructures 55 and the fin 66. To form the dummy gates 76, first, a dummy dielectric layer is formed on the fins 66 and/or the nanostructures 55. The dummy dielectric layer may be, for example, silicon oxide, silicon nitride, a combination thereof, or the like, and may be deposited or thermally grown according to acceptable techniques. A dummy gate layer is formed over the dummy dielectric layer, and a mask layer is formed over the dummy gate layer. The dummy gate layer may be deposited over the dummy dielectric layer and then planarized, such as by a CMP. The mask layer may be deposited over the dummy gate layer. The dummy gate layer may be a conductive or non-conductive material and may be selected from a group including amorphous silicon, polycrystalline-silicon (polysilicon), poly-crystalline silicon-germanium (poly-SiGe), metallic nitrides, metallic silicides, metallic oxides, and metals. The dummy gate layer may be deposited by physical vapor deposition (PVD), CVD, sputter deposition, or other techniques for depositing the selected material. The dummy gate layer may be made of other materials that have a high etching selectivity from the etching of isolation regions. The mask layer may include, for example, silicon nitride, silicon oxynitride, or the like.

Subsequently, the mask layer may be patterned using acceptable photolithography and etching techniques to form masks 78. The pattern of the masks 78 then may be transferred to the dummy gate layer and to the dummy dielectric layer to form dummy gates 76 and dummy gate dielectrics 70, respectively. The dummy gates 76 cover respective channel regions of the fins 66. The pattern of the masks 78 may be used to physically separate each of the dummy gates 76 from adjacent dummy gates 76. The dummy gates 76 may also have a lengthwise direction substantially perpendicular to the lengthwise direction of respective fins 66. It is noted that the dummy gate dielectrics 70 is shown covering only the fins 66 and the nanostructures 55 for illustrative purposes only. In some embodiments, the dummy gate dielectrics 70 may be deposited such that the dummy gate dielectrics 70 covers the STI regions 68, such that the dummy gate dielectrics 70 extends between the dummy gates 76 and the STI regions 68.

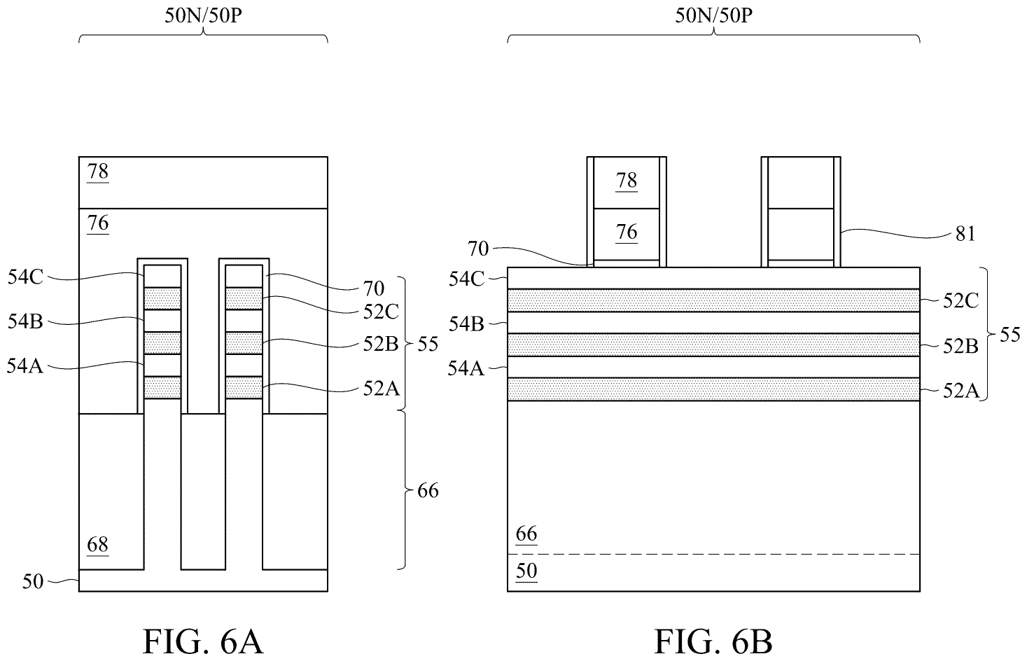

In FIGS. 6A and 6B, gate spacers 81 are formed over the nanostructures 55 and the STI regions 68, on exposed sidewalls of the masks 78 (if present), the dummy gates 76, and the dummy gate dielectrics 70. The gate spacers 81 may be formed by conformally forming one or more dielectric material(s) and subsequently etching the dielectric material(s). Acceptable dielectric materials may include silicon oxide, silicon nitride, silicon oxynitride, silicon oxycarbonitride, or the like, which may be formed by a deposition process such as chemical vapor deposition (CVD), atomic layer deposition (ALD), or the like. Other insulation materials formed by any acceptable process may be used. Any acceptable etch process, such as a dry etch, a wet etch, the like, or a combination thereof, may be performed to pattern the dielectric material(s). The etching may be anisotropic. The dielectric material(s), when etched, have portions left on the sidewalls of the dummy gates 76 (thus forming the gate spacers 81). As subsequently described in greater detail, the dielectric material(s), when etched, may also have portions left on the sidewalls of the semiconductor fins 66 and/or the nanostructures 55 (thus forming fin spacers 83, see FIG. 7C). After etching, the fin spacers 83 and/or the gate spacers 81 can have straight sidewalls (as illustrated) or can have curved sidewalls (not separately illustrated).

Further, implants for lightly doped source/drain (LDD) regions (not separately illustrated) may be performed. The LDD implants may be performed before the gate spacers 81 are formed. In embodiments with different device types, similar to the implants for the previously described wells, a mask, such as a photoresist, may be formed over the n-type region 50N, while exposing the p-type region 50P, and appropriate type (e.g., p-type) impurities may be implanted into the semiconductor fins 66 and the nanostructures 55 exposed in the p-type region 50P. The mask may then be removed. Subsequently, a mask, such as a photoresist, may be formed over the p-type region 50P while exposing the n-type region 50N, and appropriate type impurities (e.g., n-type) may be implanted into the semiconductor fins 66 and the nanostructures 55 exposed in the n-type region 50N. The mask may then be removed. The n-type impurities may be the any of the n-type impurities previously discussed, and the p-type impurities may be the any of the p-type impurities previously discussed. The lightly doped source/drain regions may have a concentration of impurities in a range from about 10¹⁵ atoms/cm³ to about 10¹⁹ atoms/cm³. An anneal may be used to repair implant damage and to activate the implanted impurities.

It is noted that the previous disclosure generally describes a process of forming spacers and LDD regions. Other processes and sequences may be used. For example, fewer or additional spacers may be utilized, different sequence of steps may be utilized, additional spacers may be formed and removed, and/or the like. Furthermore, the n-type devices and the p-type devices may be formed using different structures and steps.

In FIGS. 7A-7C, first recesses 86 are formed in the fins 66, the nanostructures 55, and the substrate 50, in accordance with some embodiments. Epitaxial source/drain regions will be subsequently formed in the first recesses 86. The first recesses 86 may extend through the first nanostructures 52 and the second nanostructures 54, and into the substrate 50. As illustrated in FIG. 7C, top surfaces of the STI regions 68 may be level with bottom surfaces of the first recesses 86. In other embodiments, the fins 66 may be etched such that bottom surfaces of the first recesses 86 are disposed above or below the top surfaces of the STI regions 68. The first recesses 86 may be formed by etching the fins 66, the nanostructures 55, and the substrate 50 using anisotropic etching processes, such as RIE, NBE, or the like. The gate spacers 81, the fin spacers 83, and the masks 78 mask portions of the fins 66, the nanostructures 55, and the substrate 50 during the etching processes used to form the first recesses 86. A single etch process or multiple etch processes may be used to etch each layer of the nanostructures 55 and/or the fins 66. Timed etch processes may be used to stop the etching of the first recesses 86 after the first recesses 86 reach a desired depth.

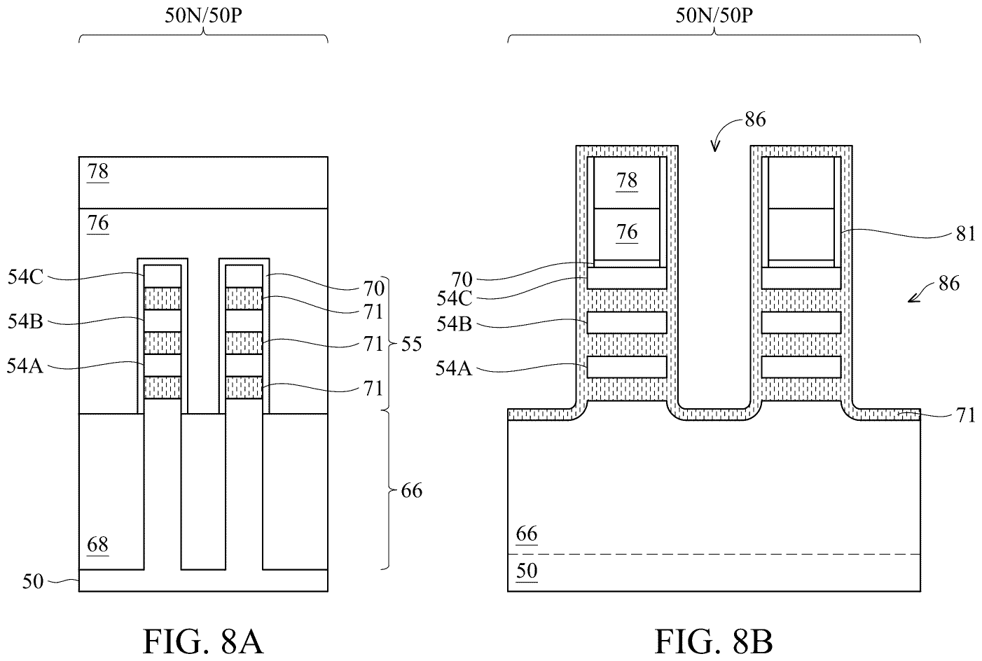

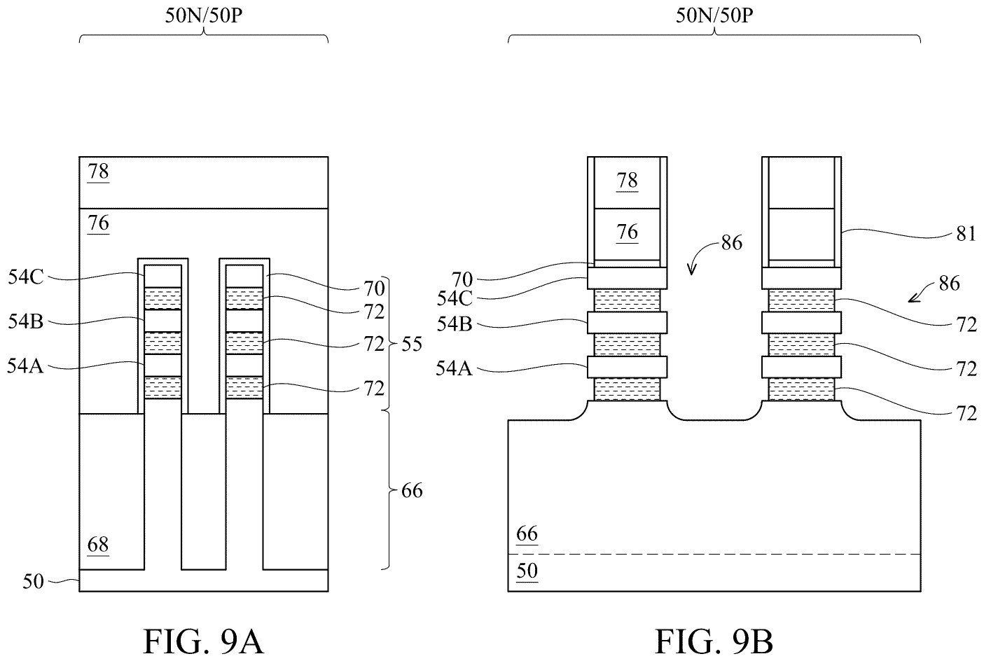

In FIGS. 8A-9B, the first nanostructures 52 are replaced with a sacrificial material 72 (also referred to as disposable oxide interposers (DOI) 72). Referring first to FIGS. 8A and 8B, replacing the first nanostructures 52 may include etching away the first nanostructures 52 using a suitable etch process, such as an isotropic etch process, that is performed through the first recesses 86. The etch process may be selective to the material of the first nanostructures 52 and remove the first nanostructures 52 without significantly removing the second nanostructures 54 or the semiconductor fins 66. In an embodiment in which the first nanostructures 52 include, e.g., SiGe, and the second nanostructures 54 include, e.g., Si or SiC, a dry etch process with tetramethylammonium hydroxide (TMAH), ammonium hydroxide (NH₄OH), or the like may be used to remove the first nanostructures 52.

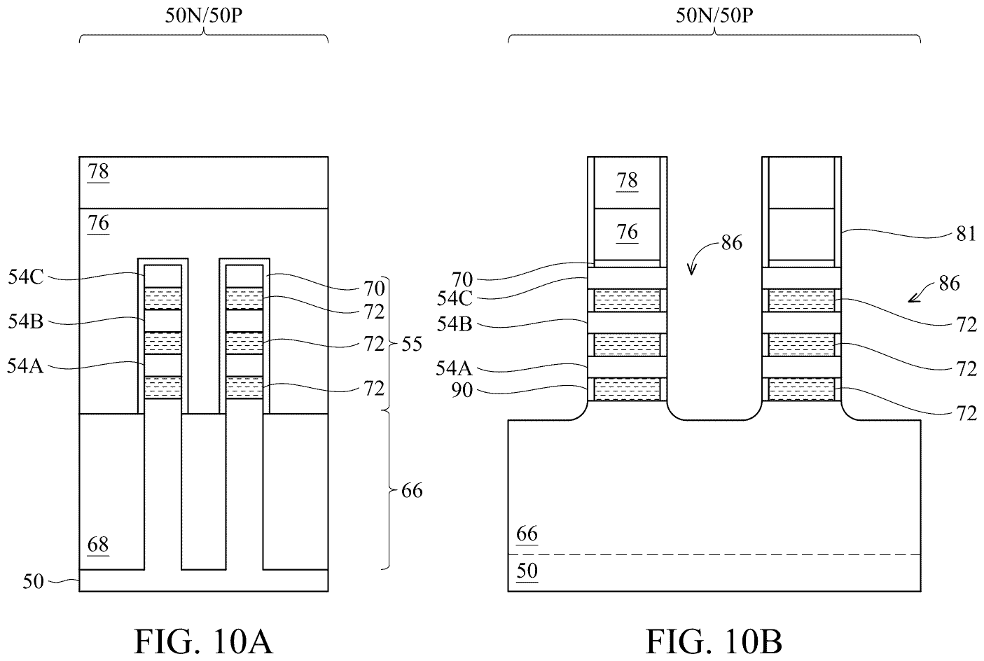

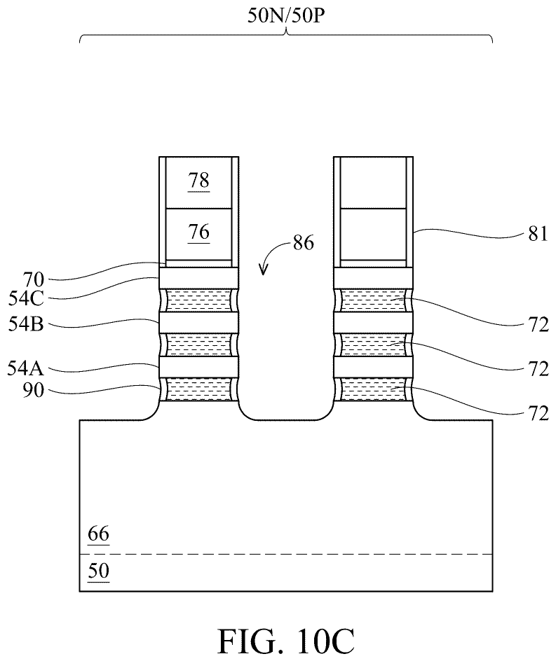

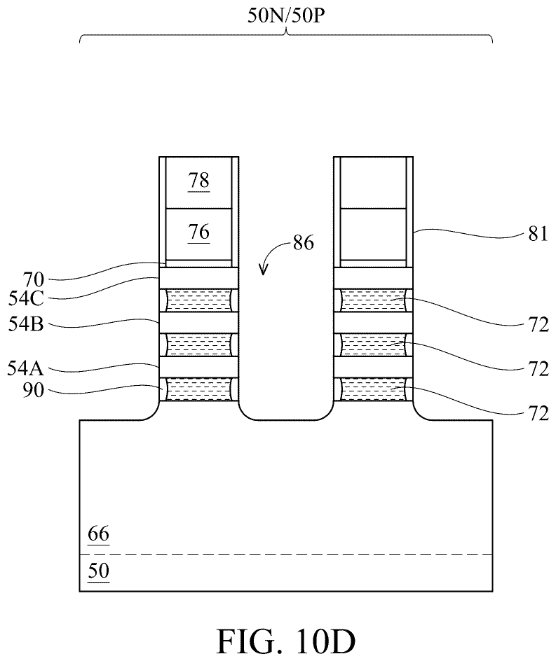

Subsequently, a sacrificial material layer 71 is deposited in the first recesses 86 and spaces where the first nanostructures 52 were removed. The sacrificial material layer 71 may be deposited by a conformal deposition process, such as CVD, ALD, or the like. The sacrificial material layer may comprise an insulating material such as silicon oxide (e.g., SiO₂), or the like that can be selectively etched from the second nanostructures 54. In FIGS. 9A and 9B, the sacrificial material layer 71 may then be etched to form the sacrificial material 72. The etching may be isotropic or anisotropic. For example, the sacrificial material layer may be etched by a wet etch process using diluted HF, or the like as an etchant. In some embodiments, the etching is performed until sidewalls of the sacrificial material 72 is recessed past sidewalls of the nanostructures 54. Although sidewalls of sacrificial material 72 are illustrated as being straight in FIG. 9B, the sidewalls may be concave or convex (see e.g., FIG. 10C).

Replacing the first nanostructures 52 with the sacrificial material 72 may provide advantages. For example, in subsequent source/drain formation steps, one or more high temperature processes may be performed to activate the dopants in the source/drain regions. When the material of the first nanostructures 52 (e.g., SiGe) is exposed to high temperatures, germanium intermixing and increased roughness at an interfaces between the nanostructures 52 and 54 may result. Such manufacturing defects may degrade the performance of the resulting transistor devices. For example, when germanium diffuses into the second nanostructures 54, germanium residue may remain in channel regions of the resulting transistor devices, which negatively affects the performance of the channel regions. By replacing the first nanostructures 52 with an insulating material (the sacrificial material 72) prior to the high temperature processes (e.g., source/drain annealing), manufacturing defects can be reduced and device performance can be improved (e.g., increased current drive, reduced capacitance, and improved short channel effect).

In FIGS. 10A and 10B, inner spacers 90 are formed in the first recesses 86 on the sidewalls of the sacrificial material 72. The inner spacers 90 act as isolation features between subsequently formed source/drain regions and a gate structure. As will be discussed in greater detail below, source/drain regions will be formed in the first recesses 86, while the sacrificial material 72 will be replaced with corresponding gate structures. The inner spacers 90 may also be used to prevent damage to subsequently formed source/drain regions by subsequent etching processes, such as etching processes used to form gate structures.

The inner spacers 90 may be formed by depositing an inner spacer layer (not separately illustrated) over the structures illustrated in FIGS. 9A and 9B. The inner spacer layer may be deposited by a conformal deposition process, such as CVD, ALD, or the like. The inner spacer layer may comprise a material such as silicon nitride or silicon oxynitride, although any suitable material, such as low-dielectric constant (low-k) materials having a k-value less than about 3.5, may be utilized. The inner spacer layer may then be anisotropically etched to form the inner spacers 90. The inner spacer layer may be etched by an anisotropic etching process, such as RIE, NBE, or the like.

Although FIG. 10B illustrates outer sidewalls of the inner spacers 90 as being flush with sidewalls of the second nanostructures 54, the outer sidewalls of the inner spacers 90 may extend beyond or be recessed from sidewalls of the second nanostructures 54 (see e.g., FIG. 10C). Moreover, although the outer sidewalls of the inner spacers 90 are illustrated as being straight in FIG. 10B, the outer sidewalls of the inner spacers 90 may be concave or convex. As an example, FIG. 10C illustrates an embodiment in which sidewalls of the sacrificial material 72 are concave, outer sidewalls of the inner spacers 90 are concave, and the inner spacers 90 are recessed from sidewalls of the second nanostructures 54. Other configurations are also possible. For example, FIG. 10D illustrates an embodiment in which sidewalls of the sacrificial material 72 are concave, outer sidewalls of the inner spacers 90 are straight, and the inner spacers 90 are flush with sidewalls of the second nanostructures 54.

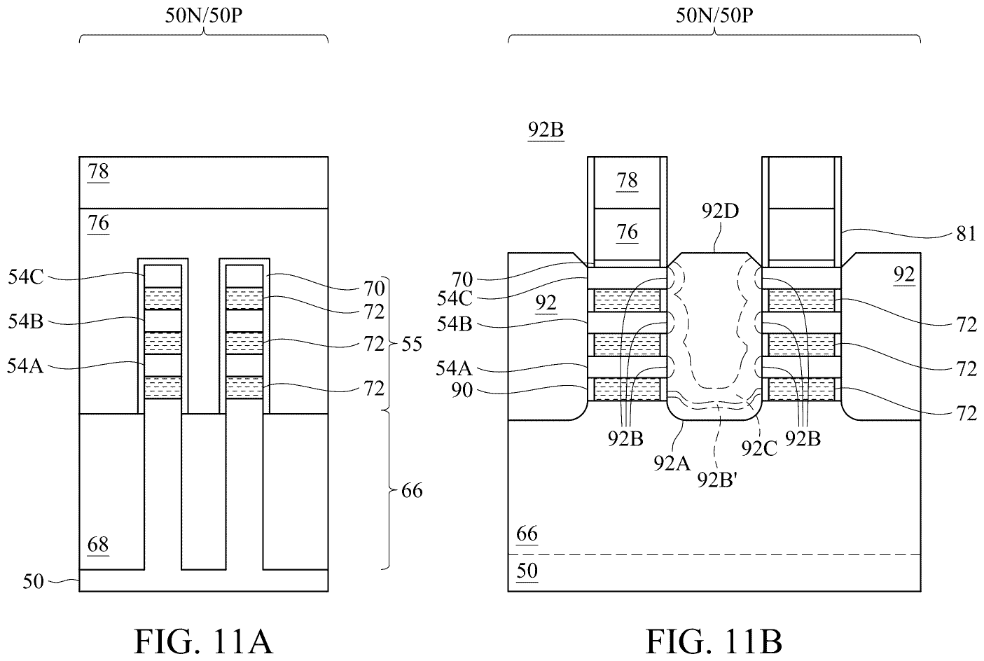

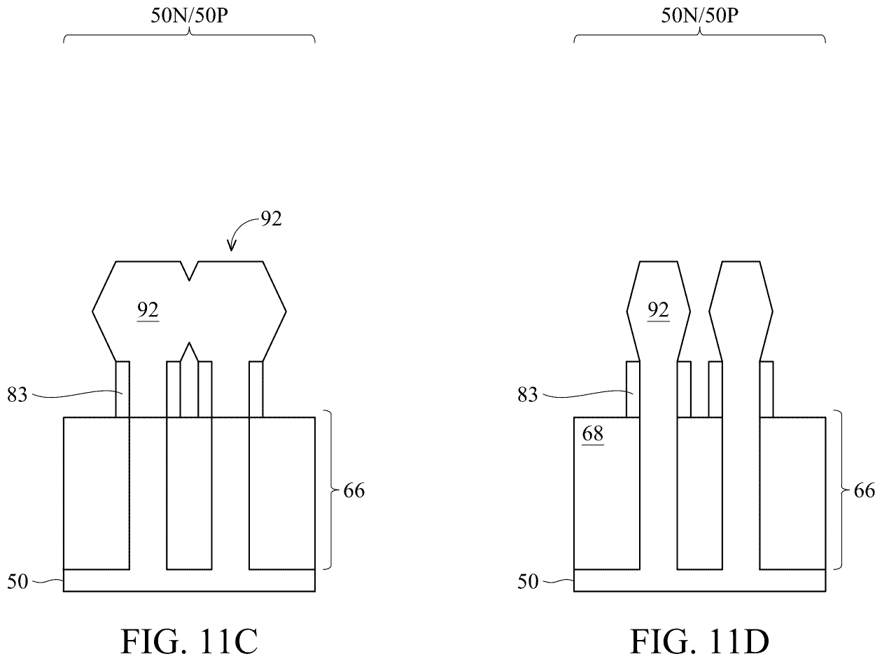

In FIGS. 11A-11D, epitaxial source/drain regions 92 are formed in the first recesses 86. In some embodiments, the source/drain regions 92 may exert stress on the second nanostructures 54 in the n-type region 50N and/or on the first nanostructures 52 in the p-type region 50P, thereby improving performance. As illustrated in FIG. 11B, the epitaxial source/drain regions 92 are formed in the first recesses 86 such that each dummy gate 76 is disposed between respective neighboring pairs of the epitaxial source/drain regions 92. In some embodiments, the gate spacers 81 are used to separate the epitaxial source/drain regions 92 from the dummy gates 76 and the inner spacers 90 are used to separate the epitaxial source/drain regions 92 from the sacrificial material 72 by an appropriate lateral distance so that the epitaxial source/drain regions 92 do not short out with subsequently formed gates of the resulting nano-FETs.

The epitaxial source/drain regions 92 in the n-type region 50N, e.g., the NMOS region, may be formed by masking the p-type region 50P, e.g., the PMOS region. Then, the epitaxial source/drain regions 92 are epitaxially grown in the first recesses 86 in the n-type region 50N. The epitaxial source/drain regions 92 may include any acceptable material appropriate for n-type nano-FETs. For example, if the second nanostructures 54 are silicon, the epitaxial source/drain regions 92 in the n-type region 50N may include materials exerting a tensile strain on the second nanostructures 54, such as silicon, silicon carbide, phosphorous doped silicon carbide, silicon phosphide, or the like.

The epitaxial source/drain regions 92 in the p-type region 50P, e.g., the PMOS region, may be formed by masking the n-type region 50N, e.g., the NMOS region. Then, the epitaxial source/drain regions 92 are epitaxially grown in the first recesses 86 in the p-type region 50P. The epitaxial source/drain regions 92 may include any acceptable material appropriate for p-type nano-FETs. For example, if the second nanostructures 54 are silicon, the epitaxial source/drain regions 92 in the p-type region 50P may include materials exerting a compressive strain on the second nanostructures 54, such as silicon-germanium, boron doped silicon-germanium, germanium, germanium tin, or the like.

The epitaxial source/drain regions 92, the second nanostructures 54, and/or the substrate 50 may be implanted with dopants to form source/drain regions, similar to the process previously discussed for forming lightly-doped source/drain regions, followed by an anneal. The source/drain regions may have an impurity concentration of between about 1×10¹⁹ atoms/cm³ and about 1×10²¹ atoms/cm³. The n-type and/or p-type impurities for source/drain regions may be any of the impurities previously discussed. In some embodiments, the epitaxial source/drain regions 92 may be in situ doped during growth.

As a result of the epitaxy processes used to form the epitaxial source/drain regions 92 in the n-type region 50N and the p-type region 50P, upper surfaces of the epitaxial source/drain regions 92 have facets which expand laterally outward beyond sidewalls of the nanostructures 55. In some embodiments, these facets cause adjacent epitaxial source/drain regions 92 of a same nano-FET to merge as illustrated by FIG. 11C. In other embodiments, adjacent epitaxial source/drain regions 92 remain separated after the epitaxy process is completed as illustrated by FIG. 11D. In the embodiments illustrated in FIGS. 11C and 11D, the fin spacers 83 may be formed on top surfaces of the STI regions 68, thereby blocking the epitaxial growth. In some other embodiments, the fin spacers 83 may cover portions of the sidewalls of the nanostructures 55 further blocking the epitaxial growth. In some other embodiments, the spacer etch used to form the fin spacers 83 may be adjusted to remove the spacer material to allow the epitaxially grown region to extend to the surface of the STI structures 68.

The epitaxial source/drain regions 92 may comprise one or more semiconductor material layers. For example, the epitaxial source/drain regions 92 may comprise a first semiconductor material layer 92A, a second semiconductor material layer 92B, a third semiconductor material layer 92C, and a fourth semiconductor material 92D. Any number of semiconductor material layers may be used for the epitaxial source/drain regions 92.

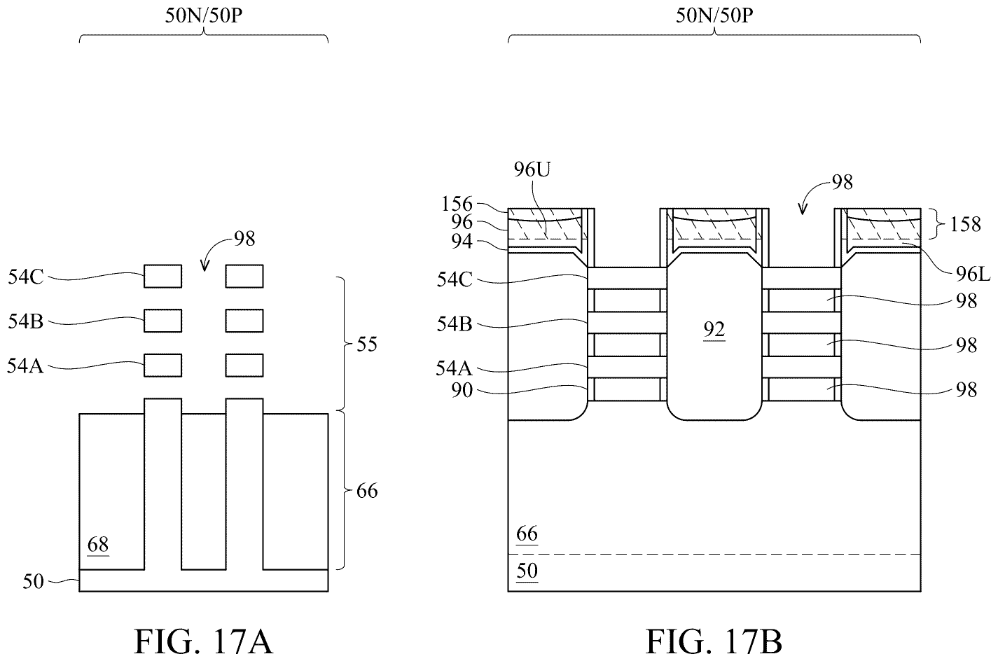

Each of the first semiconductor material layer 92A, the second semiconductor material layer 92B, the third semiconductor material layer 92C, and the fourth semiconductor material layer 92D may be formed of different semiconductor materials and may be doped to different dopant concentrations. For example, the first semiconductor material layer 92A may be a undoped or lightly doped layer that prevents or reduces diffusion of dopants from the overlying epitaxial layers (e.g., particularly the third and fourth semiconductor material layers 92C and 92D) into the underlying substrate 50. In a specific example, the first and second semiconductor material layers 92A and 92B may be silicon layers that are substantially free of germanium, and the third and fourth semiconductor material layers 92C and 92D may be silicon germanium layers. The second semiconductor material layer 92B may be high concentration, dopant layer (e.g., a high concentration boron-doped layer or the like) that is formed to increase etch selectivity along sidewalls of the second nanostructures 54 during subsequent oxide etching processes to reduce the risk of undesired etching. The oxide etching processes include processes to remove the sacrificial material 72 as described below in FIGS. 17A-17B. The second semiconductor material layer 92B may include lateral portions 92B′ that results from applying the doping process to the undoped or lightly doped first semiconductor material layer 92A. In embodiments in which the epitaxial source/drain regions 92 comprise four semiconductor material layers, the first semiconductor material layer 92A may be deposited, the second semiconductor material layer 92B may be formed by doping the first semiconductor material layer 92A with a suitable dopant and/or depositing the second semiconductor material layer 92B over the first semiconductor material layer 92A, the third semiconductor material layer 92C may be deposited over the second semiconductor material layer 92B, and the fourth semiconductor material layer 92D may be deposited over the third semiconductor material layer 92C. Other source/drain configurations are also possible in other embodiments.

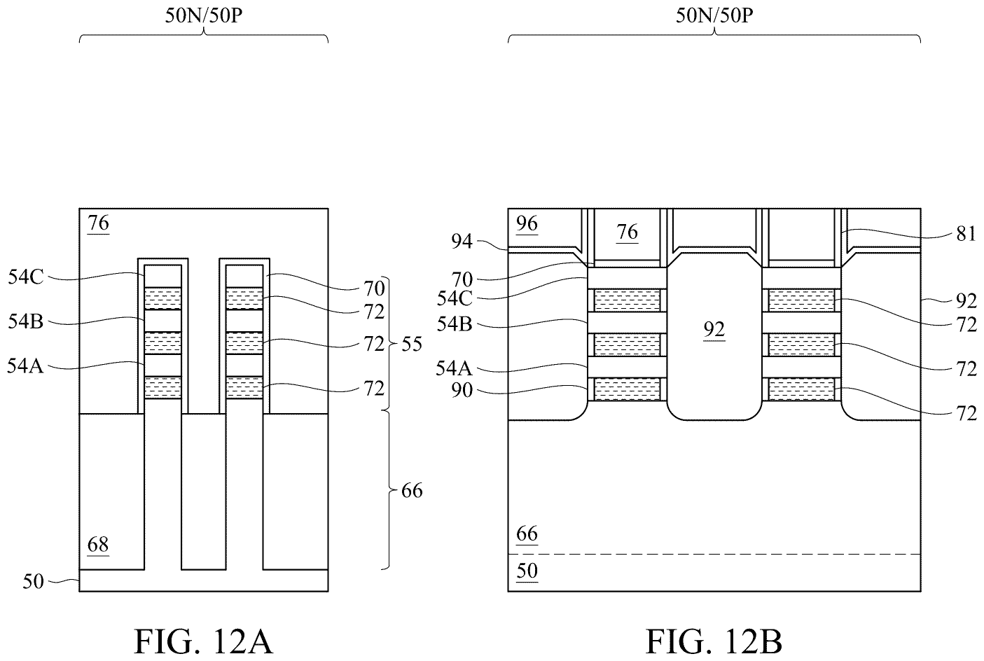

In FIGS. 12A and 12B, a first interlayer dielectric (ILD) 96 is deposited over the structure illustrated in FIGS. 11A and 11B, respectively. The first ILD 96 may be formed of a dielectric material, and may be deposited by any suitable method, such as CVD, plasma-enhanced CVD (PECVD), or FCVD. Dielectric materials may include silicon oxide, phospho-silicate glass (PSG), boro-silicate glass (BSG), boron-doped phospho-silicate glass (BPSG), undoped silicate glass (USG), or the like. Other insulation materials formed by any acceptable process may be used. In some embodiments, a contact etch stop layer (CESL) 94 is disposed between the first ILD 96 and the epitaxial source/drain regions 92, the masks 78, and the gate spacers 81. The CESL 94 may comprise a dielectric material, such as, silicon nitride, silicon oxide, silicon oxynitride, or the like, having a different etch rate than the material of the overlying first ILD 96.

After the first ILD 96 is deposited, a planarization process, such as a CMP, may be performed to level the top surface of the first ILD 96 with the top surfaces of the dummy gates 76 (as shown) or the masks 78. The planarization process may also remove the masks 78 on the dummy gates 76, and portions of the gate spacers 81 along sidewalls of the masks 78. After the planarization process, top surfaces of the dummy gates 76, the gate spacers 81, and the first ILD 96 are level within process variations. Accordingly, the top surfaces of the dummy gates 76 are exposed through the first ILD 96. In some embodiments, the masks 78 may remain, in which case the planarization process levels the top surface of the first ILD 96 with top surface of the masks 78 and the gate spacers 81.

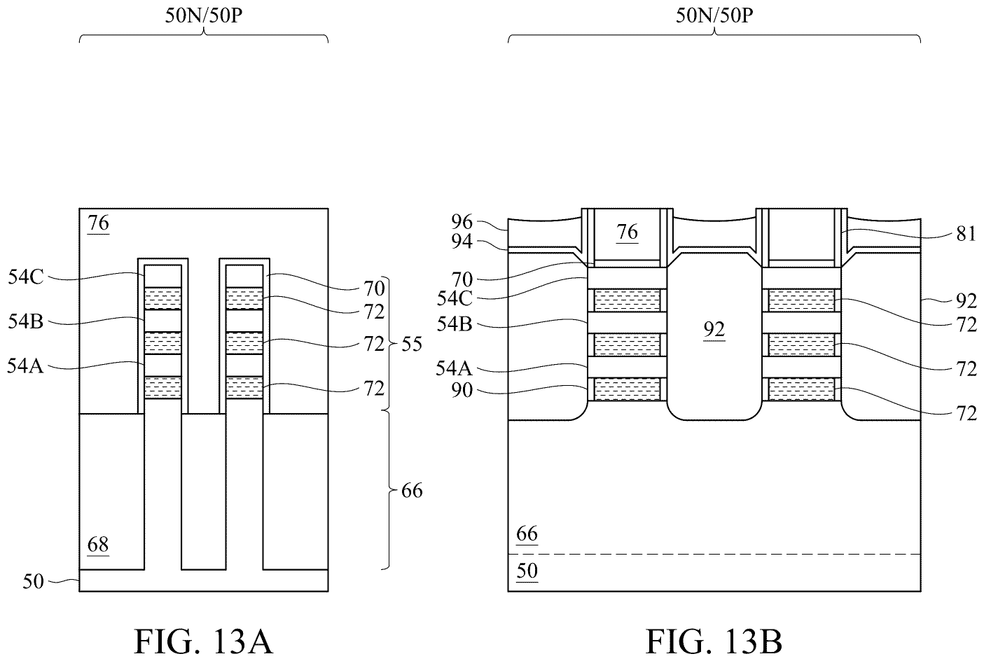

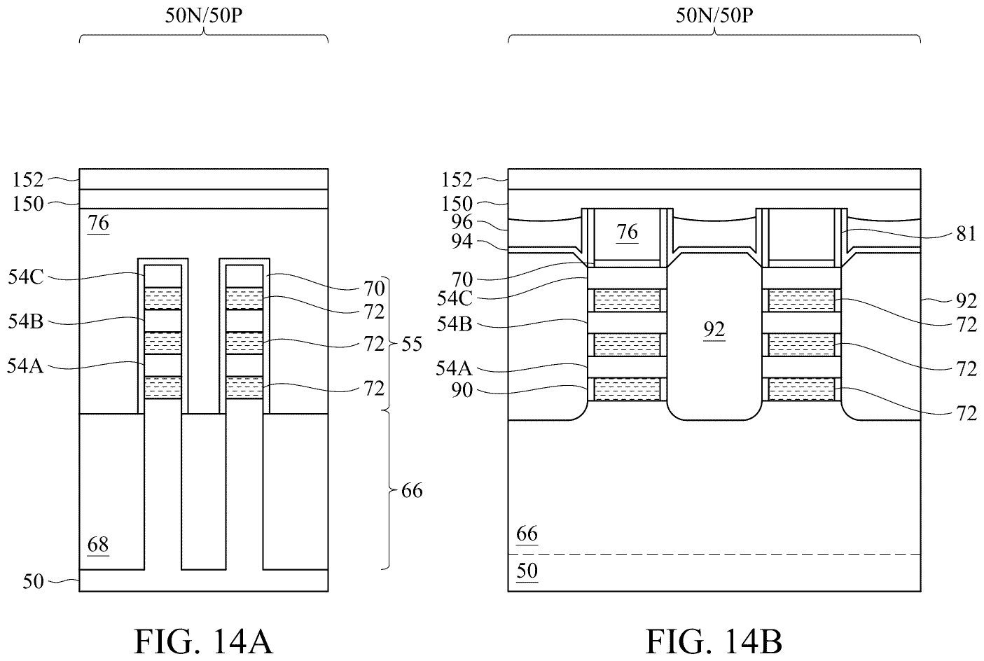

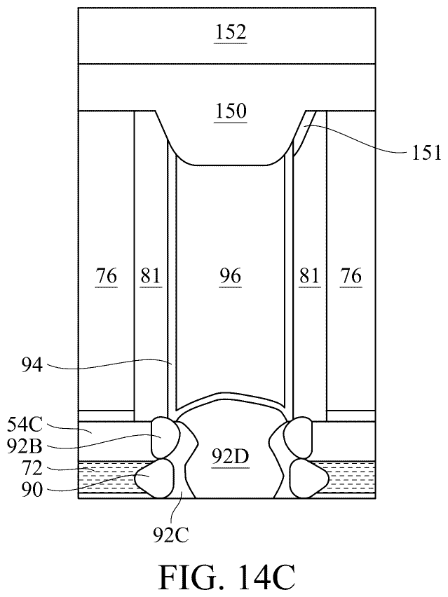

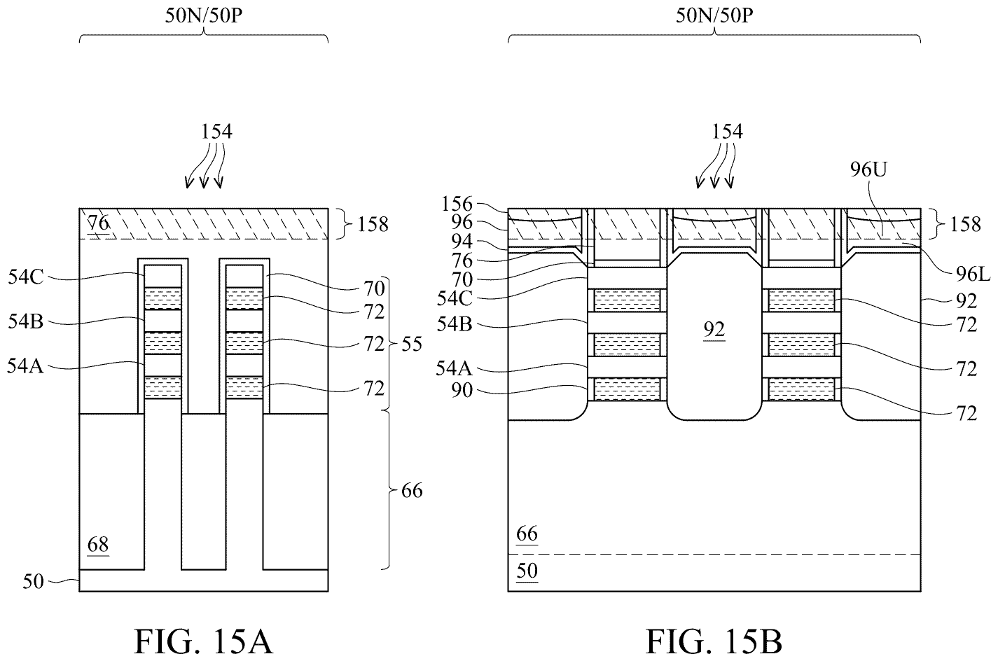

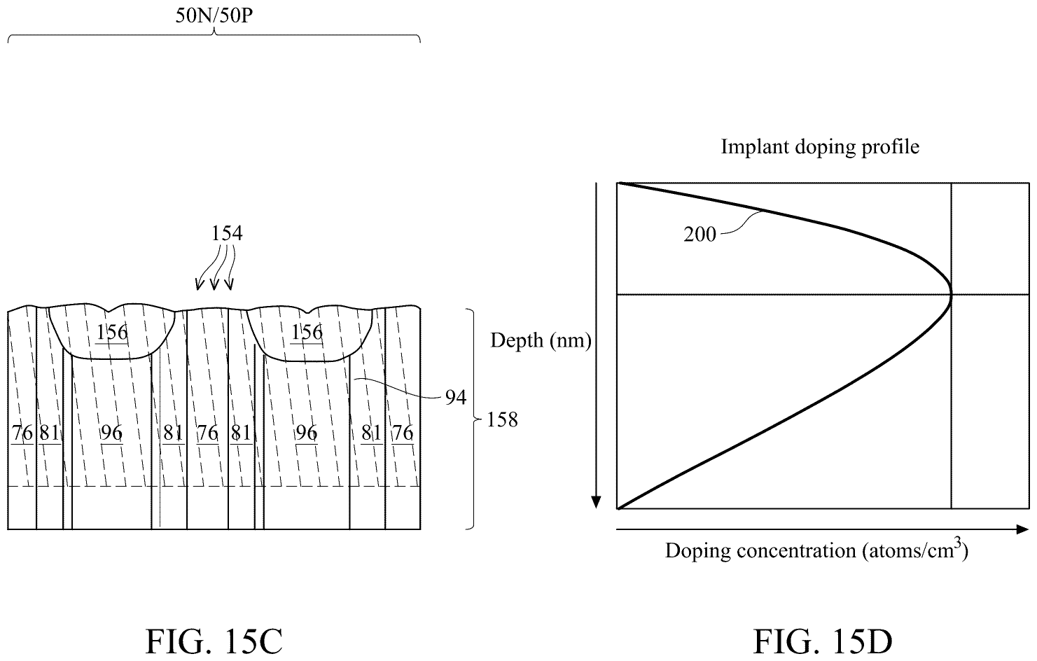

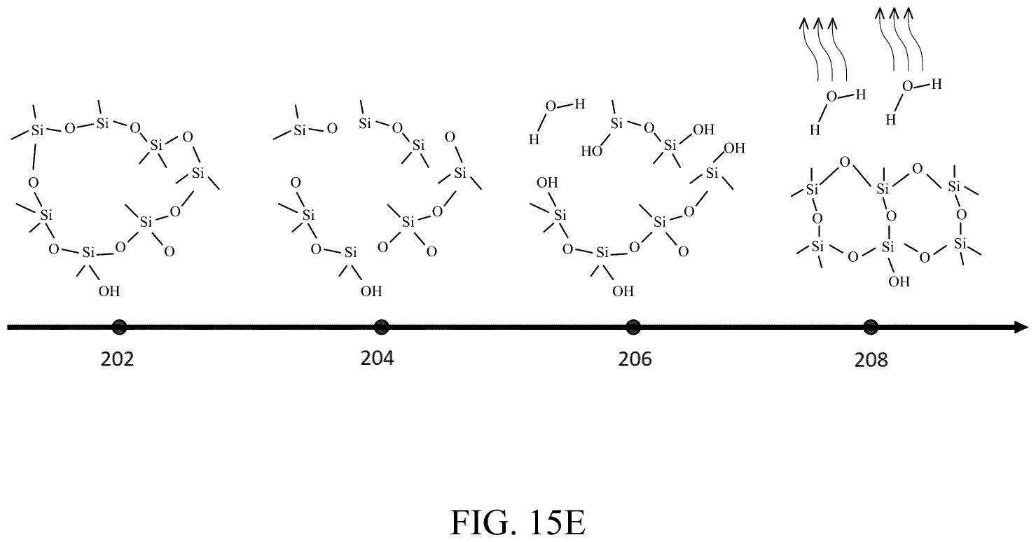

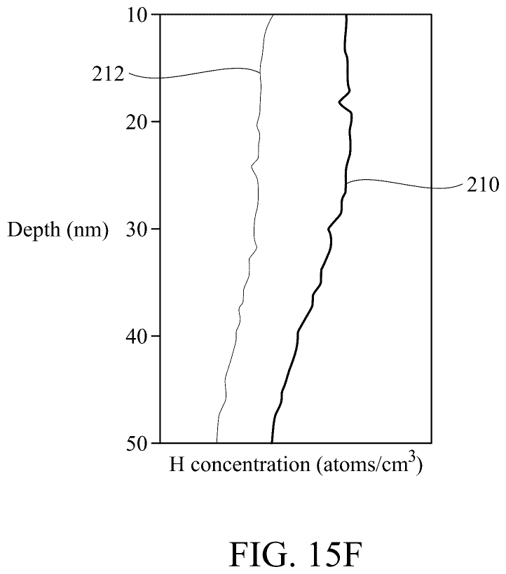

In FIGS. 13A and 13B, the first ILD 96 may be recessed below top surfaces of the dummy gates 76 and the gate spacers 81. In some embodiments, the first ILD 96 may further be recessed such that the CESL 94 extends above a top surface of the first ILD 96. Recessing the first ILD 96 may be performed using any suitable etch back process that selectively etches the first ILD 96 compared to the dummy gates 76. The etching may be anisotropic. This anisotropic etching allows for precise control of the recess depth while maintaining the lateral dimensions of the first ILD 96. Suitable etching techniques may include reactive ion etching (RIE) or plasma etching, using etchants that selectively react with the ILD material without significantly etching the dummy gates 76, the gate spacers 81, and/or the CESL 94. In some embodiments, recessing the first ILD 96 may also recess the CESL 94 and/or partially etch the gate spacers 81 (see e.g., FIGS. 14C and 15C). The degree to which the CESL 94/gate spacers 81 is etched may vary depending on the specific materials of the first ILD 96, the CESL 94, and the gate spacers 81.

In FIGS. 14A and 14B, the hard mask material layer 150 is deposited over the first ILD 96, the CESL 94, the gate spacers 81, and the dummy gates 76. The hard mask material layer 150 may be deposited onto the recessed first ILD 96 into spaces between the dummy gates 76. The hard mask material layer 150 may be formed of a dielectric material, and may be deposited by any suitable method, such as CVD, plasma-enhanced CVD (PECVD), or FCVD. Suitable dielectric materials for the hard mask material layer 150 include silicon nitride, silicon oxynitride, or the like. The hard mask material layer 150 has etch selectivity relative to the first ILD 96 and the sacrificial material 72. For example, the hard mask material layer 150 may have a lower etch rate during an oxide etching process than the first ILD 96 and the sacrificial material 72. The hard mask material layer 150 may be deposited to contact sidewalls of the CESL 94.

Alternatively in embodiments where the CESL 94 is etched back while etching the first ILD 95, the hard mask material layer 150 may also be deposited to contact sidewalls of the gate spacers 81 as illustrated by FIG. 14C. The deposition process as further illustrated in detail by FIG. 14C, the deposition process for the hard mask material layer 150 may have certain defects due to manufacturing limitations. For example, gaps 151 (also referred to as seams 151) may be present between the as-deposited hard mask material layer 150 and surrounding layers (e.g., the gate spacers 81 and/or the CESL 94). These gaps may be reduced or eliminated in subsequent implantation and anneal processes.

An optional buffer layer 152 may be deposited over the hard mask material layer 150. The buffer layer 152 may be made of oxide material, such as silicon oxide, or the like. The buffer layer 152 may reduce pattern density across the device for the subsequent planarization processes (see FIGS. 15A and 15B). By introducing this layer, the overall topography of the structure is modified, creating a more uniform surface for the planarization process. The buffer layer 152 can be deposited using various techniques such as CVD, PECVD, PVD, or the like.

In FIGS. 15A and 15B, a planarization process, such as a CMP, may be performed to level the top surface of the hard mask material layer 150 with the top surfaces of the dummy gates 76 and the gate spacers 81 within process variations. After the planarization process, the hard mask material layer 150 may be referred to as hard masks 156. The planarization process may remove the buffer layer 152 (if present). Although the buffer layer 152 may be included to prove the planarity of a top surface of the hard masks 156, limitations in the planarization process may still result in slight surface variations on the top surface of the hard masks 156. For example, FIG. 15C illustrates an embodiment where the top surfaces of the hard masks 156 include one or more divots. However, these slight deviations in the topography of the hard masks 156 may still remain within tolerance of the device manufacturing process.

After the planarization process, an implantation and annealing process 154 may be performed on the hard masks 156 to implant a suitable ion species into the hard masks 156 and improve the effectiveness of the hard masks 156. In some embodiments, the implantation and annealing process 154 is a blanket process that forms an implantation region 158 throughout the hard masks 156. The implantation region 158 may further extend into upper portions of the first ILD 96, the CESL 94, the gate spacers 81, and the dummy gates 76. In some embodiments, the implantation region 158 may not extend into lower portions of the first ILD 96, the CESL 94, the gate spacers 81, and the dummy gates 76. For example, the lower portions of the first ILD 96, the CESL 94, the gate spacers 81, and the dummy gates 76 may remain substantially free of any ion species of the implantation and annealing process 154, and/or a dopant concentration of the upper portion of the first ILD 96, the CESL 94, the gate spacers 81, and the dummy gates 76 may be greater than the dopant concentration of the lower portion of the first ILD 96, the CESL 94, the gate spacers 81, and the dummy gates 76. A depth of the implantation region 158 may be controlled by tuning one or more parameters of the implantation and annealing process 154.

The implantation and annealing process 154 includes performing an ion implantation process and a subsequent annealing process. The ion implantation process introduces specific dopants into a target material (e.g., materials of the hard masks 156 and the first ILD 96) and increases the concentration of the dopants in the target material. For example, ion species (dopants) used in the implantation process 154 can include carbon, nitrogen, silicon, boron, argon, or the like. In embodiments where the ion species are elements already present in the target material (e.g., the hard mask 156 or the first ILD 96), the implantation process may increase a concentration of the elements in the hard mask 156 and/or the upper portions 96U of the first ILD 96. For example, in embodiments where ion implantation process implants silicon, a concentration of silicon may be greater in the upper portions 96U of the first ILD 96 than the lower portions 96L of the first ILD 96. As another example, in embodiments where ion implantation process implants nitrogen, the hard mask 156 may be deposited with a stoichiometric composition of silicon nitride, and the ion implantation process may increase the concentration of nitrogen in the hard mask 156 above the stoichiometric composition.

In some embodiments, ion implantation energy of the implantation process ranges from 1 keV to 20 keV. Depending on the specific application, implantation temperature of the implantation process 154 may be in a range of −100° C. to +150° C., and the ion beam tilt angle of the implantation process can be in a range of 0° to 80°. A projected range (Rp) (e.g., the depth of the implantation region 158) of the implantation process may be between 1 and 20 nm. A dosage of the implantation process may be at least 1E20 atoms/cm³. FIG. 15D illustrates an example implantation doping profile as a result of the ion implantation process according to some embodiments. Line 200 represents the doping concentration of the implanted dopants as a function of depth within the implantation region 158. A peak doping concentration may be in a range of 2E20 atoms/cm³ to 1E22 atoms/cm³ according to some embodiments. The peak concentration may be disposed within the hard masks 150 or within the upper portions 96U of the first ILD 96. Other doping profiles are also possible in other embodiments.

After the ion implantation process, a thermal anneal (e.g., a rapid thermal anneal (RTA), a flash anneal (milli-second anneal), a furnace anneal, or the like) may then be performed. The thermal anneal may be performed at temperatures between 600° C. and 1200° C. for a duration of 1 millisecond to 2 seconds in some implementations. In some embodiments, the thermal anneal may be performed at temperatures between 900° C. and 1300° C. Further, the thermal anneal may be performed at a pressure of 1 Torr to 760 Torr in an environment that includes a carrier gas (e.g., N₂), an inert gas, combinations thereof, or the like. The thermal anneal process may be performed ex-situ (e.g., with an intervening vacuum break) with the ion implantation process. In some embodiments, the thermal anneal process is a dedicated process specific to implantation and annealing process 154 and performed immediately following the ion implantation process. In other embodiments, the thermal anneal process may be performed at a later stage, e.g., concurrently with other thermal processing steps. In such embodiments, the thermal anneal process may be performed prior to the removal of the sacrificial material 72 (e.g., see FIGS. 17A and 17B).

Performing the implantation and annealing process 154 may achieve various benefits. For example, the implantation and annealing process 154 may reduce an etch rate of the hard mask 156 and the upper portions 96U of the first ILD 96 during an oxide etching process (e.g., a wet etch process with diluted hydrofluoric acid (dHF)). For example, it has been observed that when the dosage of the ion implantation process is at least 1E20 atoms/cm³, the etch rates of the hard mask 156 and the upper portions 96U of the first ILD 96 during an oxide etch process may be effectively reduced. As a result, the hard mask 156 and the upper portions 96U of the first ILD 96 are more impervious to etching during the subsequent removal of the sacrificial material 72 (see FIGS. 17A and 17B), reducing the chances of undesired etching of the first ILD 96 and the underlying source/drain regions 92. In various embodiments, an etch rate of the upper portions 96U of the first ILD 96 that are within the implantation region 158 may be less than the lower portions 96L of the first ILD 96 that are outside of the implantation region 158 to oxide etching processes (e.g., wet etch processes with dHF or the like). Specifically, the implantation and annealing process 154 may modify the etch rate of the upper portions 96U of the first ILD 96 such that it behaves more like silicon nitride or silicon carbide during oxide etching processes.

Further, implanting ions of the above species may result in volumetric expansion of the hard masks 156, thereby sealing any gaps (e.g., gaps 151, see FIG. 14C) around the hard mask 156. For example, the implanted dopants may bond with dangling bonds in the material of the hard masks 156, thereby increasing a distance between atoms of the material of the hard masks 156 and expanding the hard masks 156. For example, when the hard masks 156 are made of silicon nitride, the ions may bond with dangling bonds to increase a distance between silicon atoms and resulting in volumetric expansion of the hard masks 156. In embodiments where nitrogen is implanted at an energy of 2.9 keV to 3.1 keV and a dosage of 1.9E15 atoms/cm³ to 2.1E15 atoms/cm³, a thickness of the hard masks 156 may increase by about 1.9%. In embodiments where argon is implanted at an energy of 16.9 keV to 17.1 keV and a dosage of 0.9E15 atoms/cm³ to 1.1E15 atoms/cm³, a thickness of the hard masks 156 may increase by about 2.4%. In embodiments where argon is implanted at an energy of 16.9 keV to 17.1 keV and a dosage of 1.9E15 atoms/cm³ to 2.1E15 atoms/cm³, a thickness of the hard masks 156 may increase by about 3.6%. In embodiments where argon is implanted at an energy of 16.9 keV to 17.1 keV and a dosage of 3.9E15 atoms/cm³ to 4.1E15 atoms/cm³, a thickness of the hard masks 156 may increase by about 3.5%. As can be seen, a degree of expansion may be adjusted by controlling one or more parameters of the ion implantation process. In some embodiments, the ion implantation process may be controlled so that the hard masks 156 expand by at least 1.36 times volumetrically. It has been observed that when the hard masks 156 expand by at least this amount due to ion implantation, various gaps (e.g., gaps 151, see FIG. 14C) between the hard masks 156 and surrounding layers (e.g., the CESL 94 or the gate spacers 81) can be filled, leakage paths can be sealed, and the hard masks 156 can more effectively block etchants from reaching the first ILD 96.

Still further, the implantation and annealing process 154 may improve a film quality of the hard masks 156 and the upper portions 96U of the first ILD 96 by driving out impurities (e.g., hydroxyl groups/moisture) and increasing a density of materials within the implantation region 158. As a result of the implantation and annealing process 154, a density of the upper portions 96U of the first ILD 96 may be greater than a density of the lower portions 96L of the first ILD 96. For example, the ion implantation may break bonds within the implantation region 158, the broken bonds may bond with ambient oxygen during a vacuum break between the ion implantation and the thermal anneal, and the thermal anneal may drive out water (e.g., dehydration), thereby densifying the hard masks 156 and/or the first ILD 96. FIG. 15E illustrates schematic explaining the film improvement process within the upper portions 96U of the first ILD 96 according to some embodiments. Step 202 illustrates a composition of the first ILD 96 prior to the implantation and annealing process 154. Step 204 illustrates the composition of the upper portions 96U of the first ILD 96 as a result of the ion implantation process, which breaks bonds within the upper portions 96U of the first ILD 96. Step 206 illustrates absorption of ambient oxygen, for example, during a vacuum break between the ion implantation process and the thermal anneal. As illustrated in FIG. 206, the ambient oxygen may bond with the broken bonds that resulted from the ion implantation process depicted in step 204. The ambient oxygen may bond with excess hydrogen impurities to form water within the upper portions 96U of the first ILD 96 first ILD 96. Then in step 208, the thermal anneal process drives out the water through dehydration, thereby removing impurities and improving film quality of the upper portions 96U of the first ILD 96.

FIG. 15F illustrates experimental data of a concentration of impurities (e.g., hydrogen) in the upper portions 96U of the first ILD 96 before and after the implantation and annealing process 154. Specifically, line 210 illustrates a hydrogen concentration in the upper portions 96U of the first ILD 96 before the implantation and annealing process 154, and line 212 illustrates the hydrogen concentration in the upper portions 96U of the first ILD 96 after the implantation and annealing process 154. As illustrated, the impurity concentration may be reduced by about 38%, which indicates that the upper portions 96U of the first ILD 96 are densified. By densifying the materials of the implantation region 158, the etching rate of these materials (e.g., the materials of the hard mask 156 and upper portions of the first ILD 96, the CESL 94, and the gate spacers 81) during an oxide etching process may be further reduced. Additionally, oxide film quality improvement within the first ILD 96 has the additional benefit of reducing potential interfacial layer regrowth due to external moisture penetrating through the first ILD 96, advantageously reducing capacitance equivalent thickness (CET) in the device.

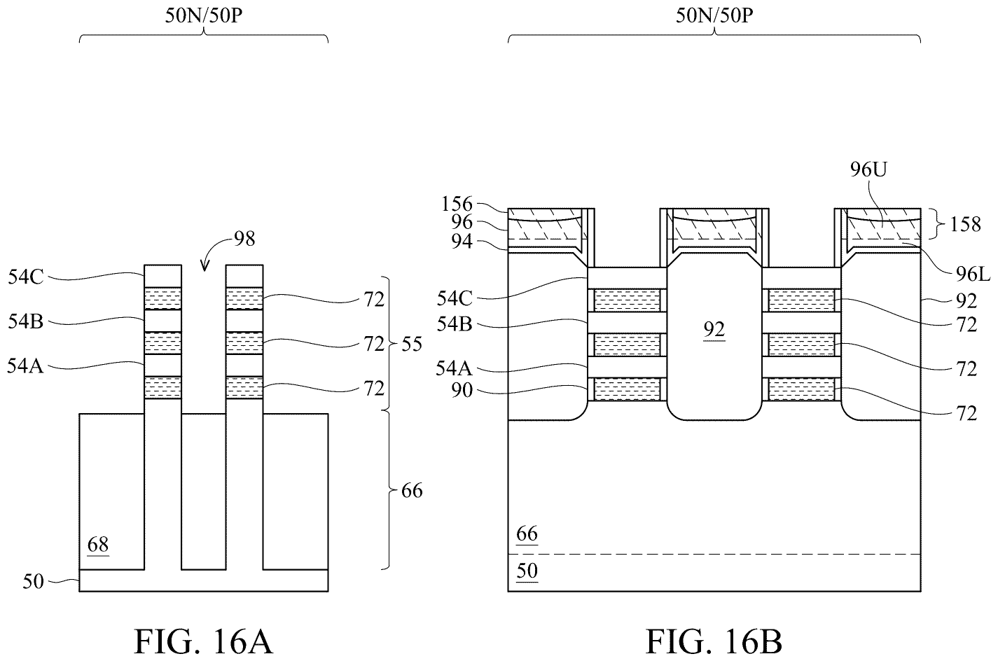

In FIGS. 16A and 16B, the dummy gates 76 are removed in one or more etching steps, so that second recesses 98 are formed. Portions of the dummy gate dielectrics 70 in the second recesses 98 may also be removed. In some embodiments, the dummy gates 76 and the dummy gate dielectrics 70 are removed by an anisotropic dry etch process. For example, the etching process may include a dry etch process using reaction gas(es) that selectively etch the dummy gates 76 at a faster rate than the hard masks 156, the first ILD 96, or the gate spacers 81. Each second recess 98 exposes and/or overlies portions of nanostructures 55, which act as channel regions in subsequently completed nano-FETs. Portions of the nanostructures 55 which act as the channel regions are disposed between neighboring pairs of the epitaxial source/drain regions 92. During the removal, the dummy gate dielectrics 70 may be used as etch stop layers when the dummy gates 76 are etched. The dummy gate dielectrics 70 may then be removed after the removal of the dummy gates 76.

In FIGS. 17A and 17B, the sacrificial material 72 is removed, extending the second recesses 98. Removing the sacrificial material 72 may include performing an isotropic etching process such as wet etching or the like using etchants which are selective to the materials of the sacrificial material 72, while the second nanostructures 54 remain relatively unetched as compared to the sacrificial material 72. The sacrificial material 72 may be completely removed, or a residue of the sacrificial material 72 may remain on sidewalls of the inner spacers in the second recesses 98 (see e.g., FIG. 15C).

Removing the sacrificial material 72 may include an oxide etch process, such as dry etch process, a wet etch process using dHF as an etchant, or the like. The first ILD 96 may be protected from inadvertent etching by the implantation region 158, including the hard masks 156 and the upper portions 96U of the first ILD 96. As explained above, the implantation and annealing process 154 may reduce an etch rate of the hard masks 156 and the upper portions 96U to the oxide etch process compared to sacrificial material 72; fill any gaps around the hard masks 156 by expanding the hard masks 156; and improving a film quality of the hard masks 156 and the upper portions 96U of the first ILD 96. As a result, manufacturing defects can be reduced and yield can be improved.

In some embodiments, the STI regions 68 may be etched while removing the sacrificial material 72, but the total amount of loss in the STI regions 68 may be reduced by controlling etching parameters (e.g., timing) while removing the sacrificial material 72. In other embodiments, the STI regions 68 may include a hard mask (not separately illustrated) at a top surface to protect the underlying STI regions 68 from etching while patterning and removing the sacrificial material 72. In such embodiments, the hard mask may comprise, for example, a nitride.

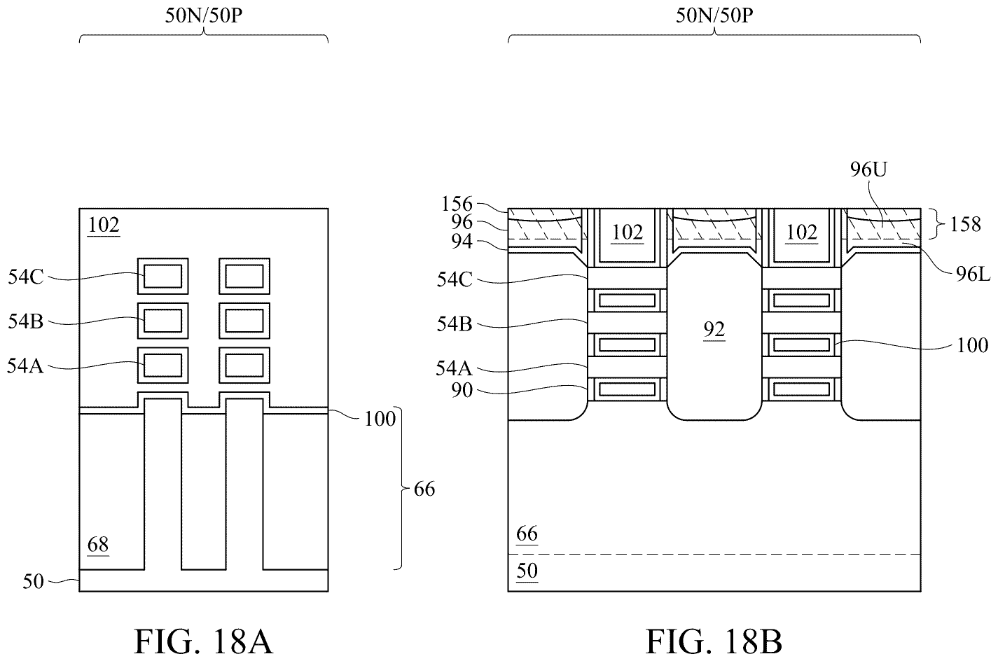

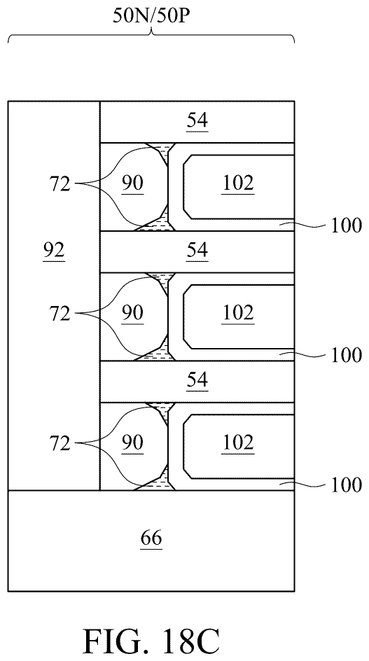

In FIGS. 18A-18C, gate dielectric layers 100 and gate electrodes 102 are formed for replacement gates. The gate dielectric layers 100 are deposited conformally in the second recesses 98. The gate dielectric layers 100 may be formed on top surfaces and sidewalls of the substrate 50 and on top surfaces, sidewalls, and bottom surfaces of the second nanostructures 54. The gate dielectric layers 100 may also be deposited on top surfaces of the first ILD 96, the CESL 94, the gate spacers 81, and the STI regions 68.

In accordance with some embodiments, the gate dielectric layers 100 comprise one or more dielectric layers, such as an oxide, a metal oxide, the like, or combinations thereof. For example, in some embodiments, the gate dielectrics may comprise a silicon oxide layer and a metal oxide layer over the silicon oxide layer. In some embodiments, the gate dielectric layers 100 include a high-k dielectric material, and in these embodiments, the gate dielectric layers 100 may have a k value greater than about 7.0, and may include a metal oxide or a silicate of hafnium, aluminum, zirconium, lanthanum, manganese, barium, titanium, lead, and combinations thereof. The structure of the gate dielectric layers 100 may be the same or different in the n-type region 50N and the p-type region 50P. The formation methods of the gate dielectric layers 100 may include molecular-beam deposition (MBD), ALD, PECVD, and the like.

The gate electrodes 102 are deposited over the gate dielectric layers 100, respectively, and fill the remaining portions of the second recesses 98. The gate electrodes 102 may include a metal-containing material such as titanium nitride, titanium oxide, tantalum nitride, tantalum carbide, cobalt, ruthenium, aluminum, tungsten, combinations thereof, or multi-layers thereof. For example, although single layer gate electrodes 102 are illustrated in FIGS. 15A-15C, the gate electrodes 102 may comprise any number of liner layers, any number of work function tuning layers, and a fill material. Any combination of the layers which make up the gate electrodes 102 may be deposited in the n-type region 50N between adjacent ones of the second nanostructures 54 and between the second nanostructure 54A and the substrate 50, and may be deposited in the p-type region 50P between adjacent ones of the first nanostructures 52.

The formation of the gate dielectric layers 100 in the n-type region 50N and the p-type region 50P may occur simultaneously such that the gate dielectric layers 100 in each region are formed from the same materials, and the formation of the gate electrodes 102 may occur simultaneously such that the gate electrodes 102 in each region are formed from the same materials. In some embodiments, the gate dielectric layers 100 in each region may be formed by distinct processes, such that the gate dielectric layers 100 may be different materials and/or have a different number of layers, and/or the gate electrodes 102 in each region may be formed by distinct processes, such that the gate electrodes 102 may be different materials and/or have a different number of layers. Various masking steps may be used to mask and expose appropriate regions when using distinct processes.

After the filling of the second recesses 98, a planarization process, such as a CMP, may be performed to remove the excess portions of the gate dielectric layers 100 and the material of the gate electrodes 102, which excess portions are over the top surface of the first ILD 96. The remaining portions of material of the gate electrodes 102 and the gate dielectric layers 100 thus form replacement gate structures of the resulting nano-FETs. The gate electrodes 102 and the gate dielectric layers 100 may be collectively referred to as “gate structures.”

FIG. 18C illustrates a detailed view of various elements of FIG. 18B, including the epitaxial source/drain regions 92, the gate dielectric layers 100, the gate electrodes 102, the second nanostructures 54, and the inner spacers 90. In some embodiments, as illustrated by FIG. 18C, a residue of the sacrificial material 72 may remain on the inner spacers 90, such as between the inner spacers 90 and the gate dielectric layers 100/gate electrodes 102. For example, the sacrificial material 72 may not be fully removed, and the gate dielectric layers 100 may be formed on the remaining sacrificial material 72. Because the sacrificial material 72 is an insulating material (e.g., silicon oxide), the remaining residue may not significantly impact the electrical performance of the resulting device.

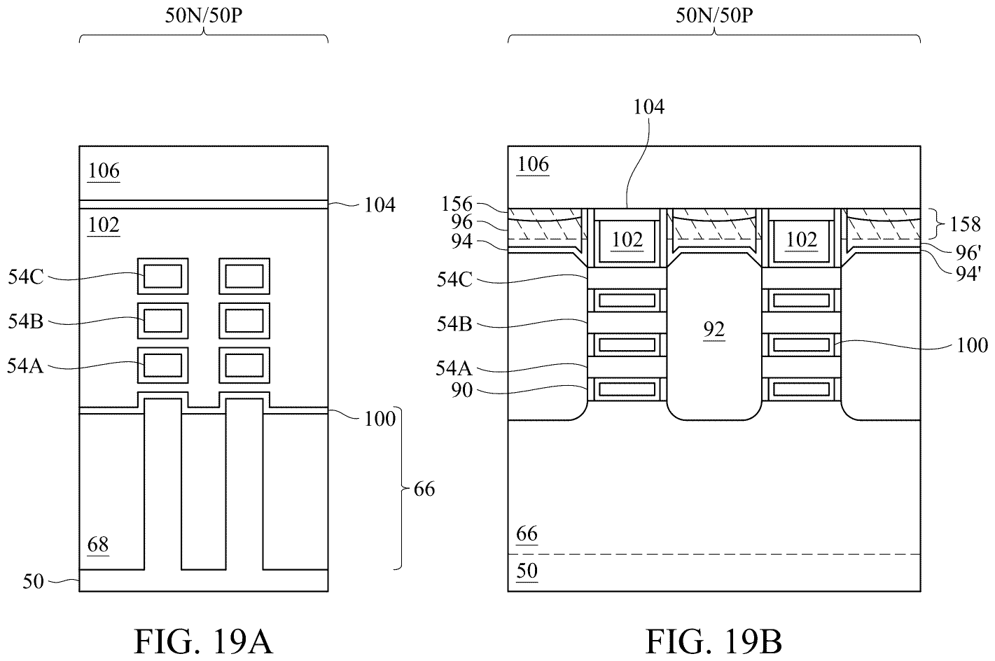

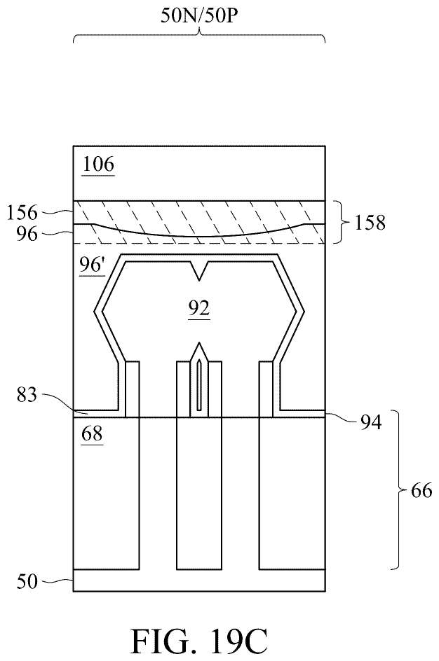

In FIGS. 19A-19C, the gate structure (including the gate dielectric layers 100 and the corresponding overlying gate electrodes 102) is recessed, so that a recess is formed directly over the gate structure and between opposing portions of gate spacers 81. A gate mask 104 comprising one or more layers of dielectric material, such as silicon nitride, silicon oxynitride, or the like, is filled in the recess, followed by a planarization process to remove excess portions of the dielectric material extending over the first ILD 96. Subsequently formed gate contacts (such as the gate contacts 114, discussed below with respect to FIGS. 18A-18C) penetrate through the gate mask 104 to contact the top surface of the recessed gate electrodes 102.

As further illustrated by FIGS. 19A-19C, a second ILD 106 is deposited over the first ILD 96 and over the gate mask 104. In some embodiments, the second ILD 106 is a flowable film formed by FCVD. In some embodiments, the second ILD 106 is formed of a dielectric material such as PSG, BSG, BPSG, USG, or the like, and may be deposited by any suitable method, such as CVD, PECVD, or the like.

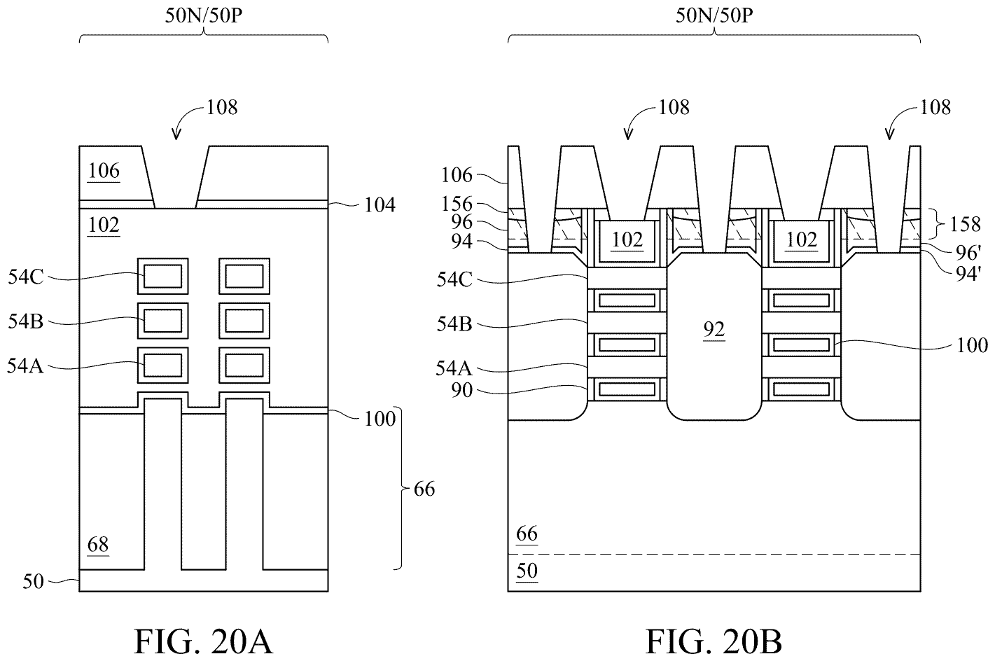

In FIGS. 20A-20C, the second ILD 106, the first ILD 96, the CESL 94, and the gate masks 104 are etched to form third recesses 108 exposing surfaces of the epitaxial source/drain regions 92 and/or the gate structure. The third recesses 108 may be formed by etching using an anisotropic etching process, such as RIE, NBE, or the like. In some embodiments, the third recesses 108 may be etched through the second ILD 106 and the first ILD 96 using a first etching process; may be etched through the gate masks 104 using a second etching process; and may then be etched through the CESL 94 using a third etching process. A mask, such as a photoresist, may be formed and patterned over the second ILD 106 to mask portions of the second ILD 106 from the first etching process and the second etching process. In some embodiments, the etching process may over-etch, and therefore, the third recesses 108 extend into the epitaxial source/drain regions 92 and/or the gate structure, and a bottom of the third recesses 108 may be level with (e.g., at a same level, or having a same distance from the substrate), or lower than (e.g., closer to the substrate) the epitaxial source/drain regions 92 and/or the gate structure. Although FIG. 17B illustrate the third recesses 108 as exposing the epitaxial source/drain regions 92 and the gate structure in a same cross section, in various embodiments, the epitaxial source/drain regions 92 and the gate structure may be exposed in different cross-sections, thereby reducing the risk of shorting subsequently formed contacts.

After the third recesses 108 are formed, silicide regions 110 are formed over the epitaxial source/drain regions 92. In some embodiments, the silicide regions 110 are formed by first depositing a metal (not shown) capable of reacting with the semiconductor materials of the underlying epitaxial source/drain regions 92 (e.g., silicon, silicon germanium, germanium) to form silicide or germanide regions. For example, metals such as nickel, cobalt, titanium, tantalum, platinum, tungsten, other noble metals, other refractory metals, rare earth metals or their alloys, may be used. The metal may be deposited over the exposed portions of the epitaxial source/drain regions 92. A thermal annealing process may then be utilized to form the silicide regions 110. The un-reacted portions of the deposited metal are then removed, e.g., by an etching process. Although silicide regions 110 are referred to as silicide regions, silicide regions 110 may also be germanide regions, or silicon germanide regions (e.g., regions comprising silicide and germanide). In an embodiment, the silicide region 110 comprises TiSi, and has a thickness in a range between about 2 nm and about 10 nm.

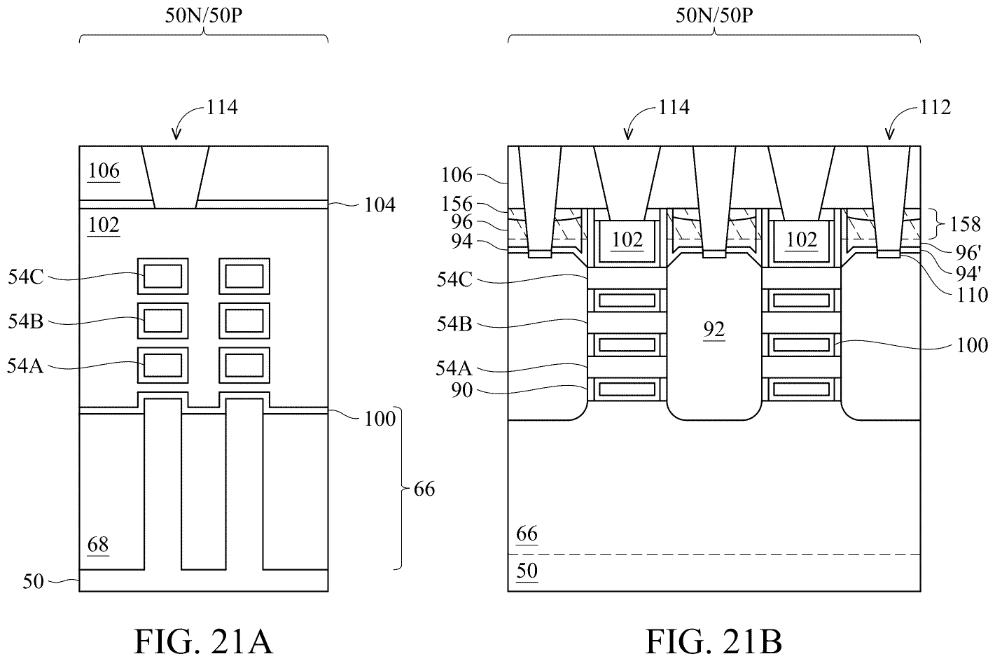

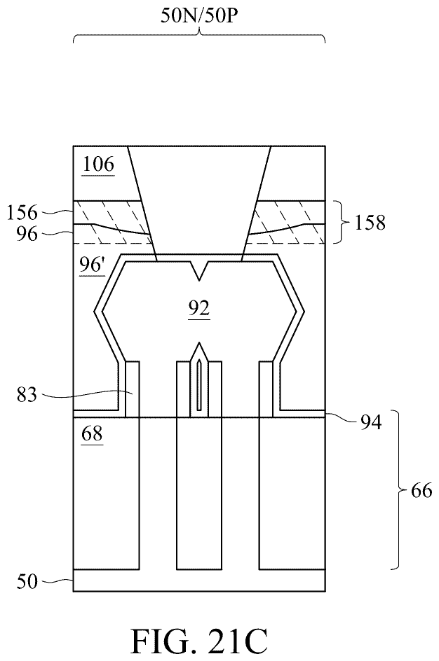

Next, in FIGS. 21A-21C, contacts 112 and 114 (may also be referred to as contact plugs) are formed in the third recesses 108. The contacts 112 and 114 may each comprise one or more layers, such as barrier layers, diffusion layers, and fill materials. For example, in some embodiments, the contacts 112 and 114 each include a barrier layer and a conductive material, and are electrically coupled to the underlying conductive feature (e.g., gate structure 102 and/or silicide region 110 in the illustrated embodiment). The contacts 114 are electrically coupled to the gate structure 102 and may be referred to as gate contacts, and the contacts 112 are electrically coupled to the silicide regions 110 and may be referred to as source/drain contacts. The barrier layer may include titanium, titanium nitride, tantalum, tantalum nitride, or the like. The conductive material may be copper, a copper alloy, silver, gold, tungsten, cobalt, aluminum, nickel, or the like. A planarization process, such as a CMP, may be performed to remove excess material from a surface of the second ILD 106.

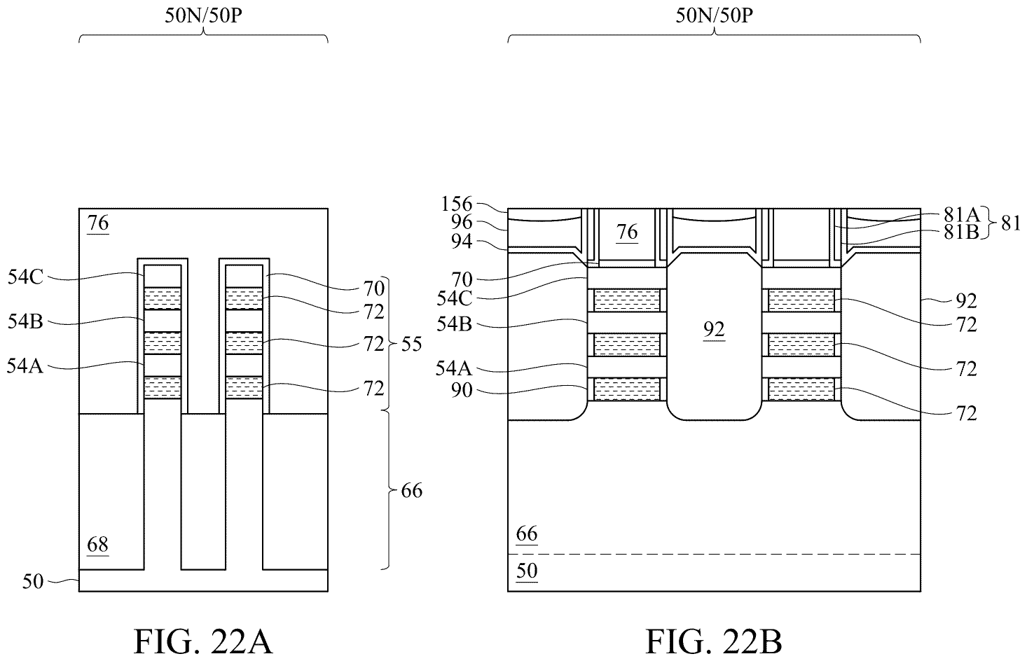

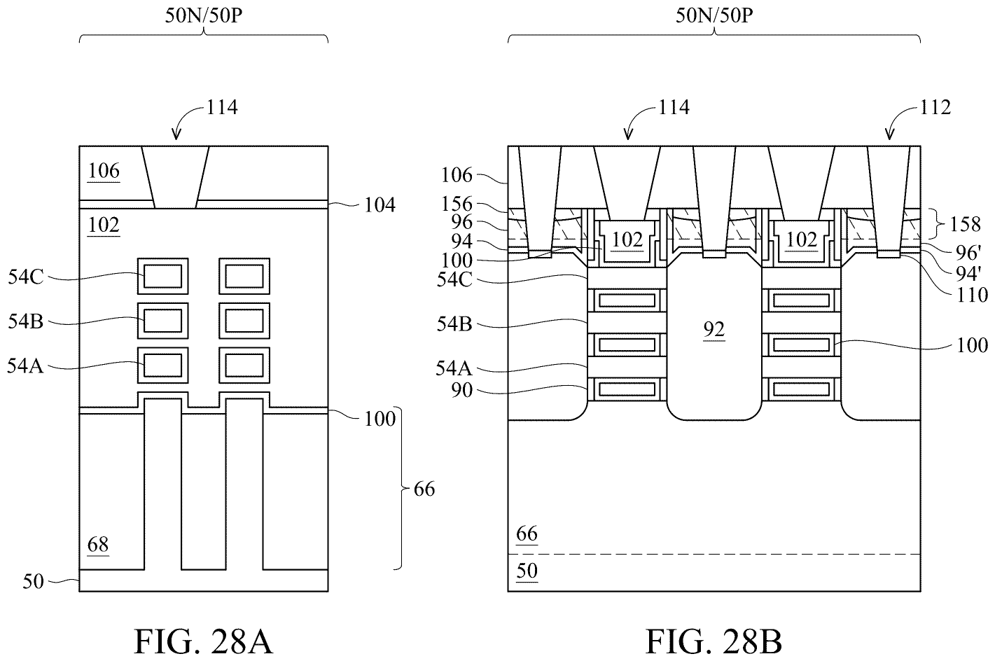

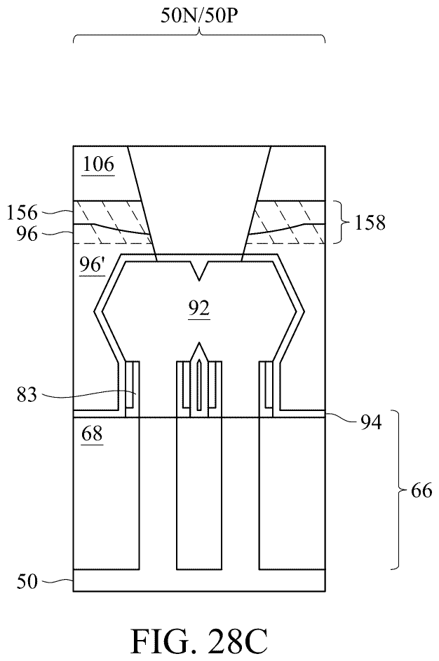

FIGS. 22A through 28C are cross-sectional views of intermediate stages in the manufacturing of nano-FETs, in accordance with some embodiments. FIGS. 22A, 23A, 24A, 25A, 26A, 27A, and 28A illustrate reference cross-section A-A′ illustrated in FIG. 1. FIGS. 22B, 23B, 24B, 25B, 26B, 27B, and 28B illustrate reference cross-section B-B′ illustrated in FIG. 1. FIG. 28C illustrates reference cross-section C-C′ illustrated in FIG. 1. Referring first to FIGS. 22A and 22B, a device at a same stage of processing as described above in FIGS. 15A through 15C is illustrated where like reference numerals indicate like elements formed by like processes. FIGS. 22A and 22B illustrate a manufacturing stage after recessing the first ILD 96, depositing a hard mask material layer (e.g., hard mask material layer 150, described above), and planarizing the hard mask material layer 150 to form the hard masks 156 but prior to the implantation and annealing process 154.

In FIGS. 22A and 22B, the gate spacers 81 is a multi-layer structure including first gate spacers 81A and second gate spacers 81B over the first gate spacers 81A. The first gate spacers 81A and second gate spacers 81B may be formed by conformally forming at least two dielectric materials and subsequently etching the dielectric materials. Acceptable dielectric materials may include silicon oxide, silicon nitride, silicon oxynitride, silicon oxycarbonitride, or the like, which may be formed by a deposition process such as CVD, ALD, or the like. The first gate spacers 81A and second gate spacers 81B may be made of different materials that can be selectively etched relative to each other. For example, the first gate spacers 81A may be made of an oxide, or the like while the second gate spacers 81B may be made of a nitride. Other combinations of insulation materials formed by any acceptable process may be used. Any acceptable etch process, such as a dry etch, a wet etch, the like, or a combination thereof, may be performed to pattern the dielectric material(s). The etching may be anisotropic. The dielectric material(s), when etched, have L-shaped portions left on the sidewalls of the dummy gates 76 (thus forming the first gate spacers 81A) and portions over the L-shaped portions (thus forming the second gate spacers 81B).

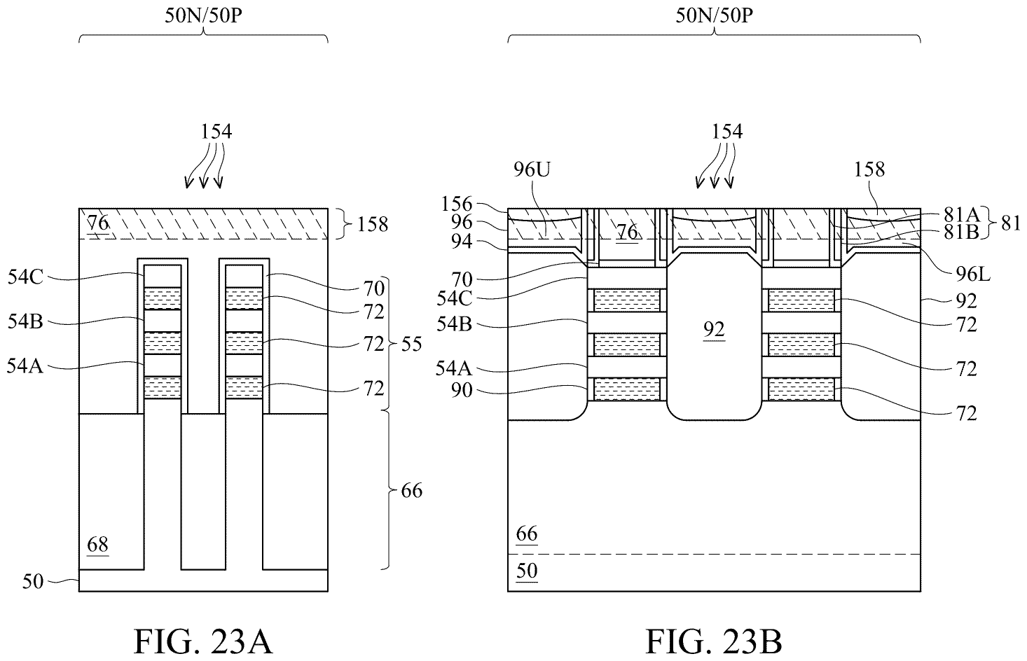

In FIGS. 23A and 23B, the implantation and annealing process 154 as described above in FIGS. 15A through 15F is performed. The implantation and annealing process 154 may include implanting carbon, nitrogen, silicon, boron, argon, or the like to form implantation regions 158 and performing a thermal anneal. As a result of the implantation and annealing process 154, the hard mask 156 and upper portions 96U of the first ILD 96 may have a lower etch rate to oxide etching processes and have improved film quality. Further, the implantation process may cause volumetric expansion of the hard mask 156, thereby filling any gaps that may surround the hard mask 156 and providing a stronger interface between the hard mask 156 and surrounding layers.

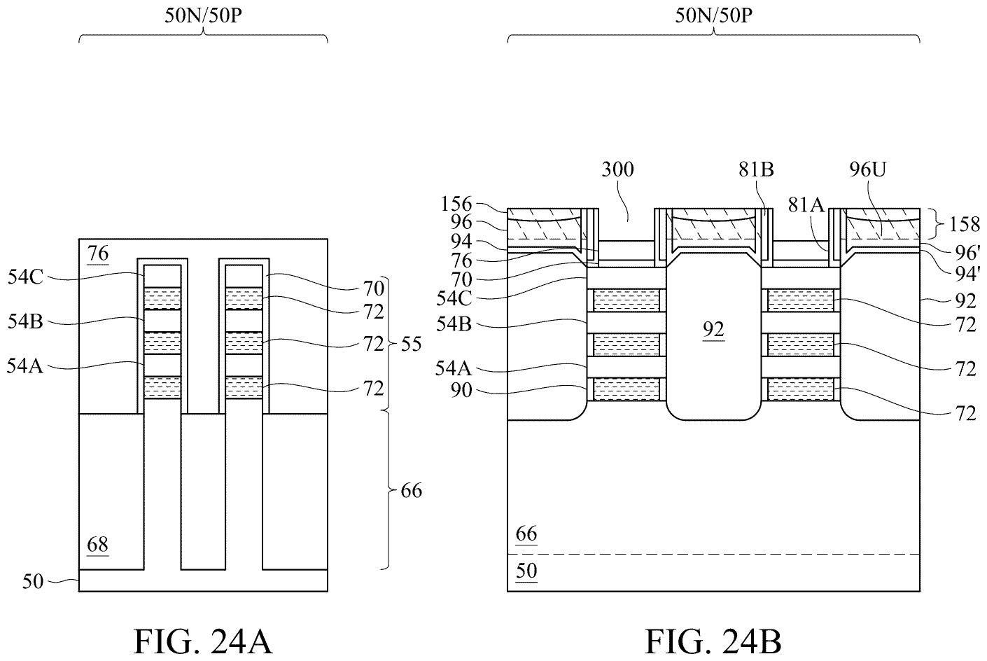

In FIGS. 24A through 26B, the dummy gates 76 are removed in various etching steps, so that recesses 300 are formed. Portions of the first gate spacers 81A and portions of the dummy gate dielectrics 70 may also be removed. In some embodiments, the dummy gates 76, portions of the first gate spacers 81A, and the dummy gate dielectrics 70 are removed by an anisotropic dry etch process. For example, in FIGS. 24A and 24B, the dummy gates 76 are etched back to a desired thickness using an time etch process. The etching process may include a dry etch process using reaction gas(es) that selectively etch the dummy gates 76 at a faster rate than the hard mask 156, the first ILD 96, or the gate spacers 81. Etching back the dummy gates 76 may define the recesses 300 and expose portions of the second gate spacers 81B in the recesses 300.

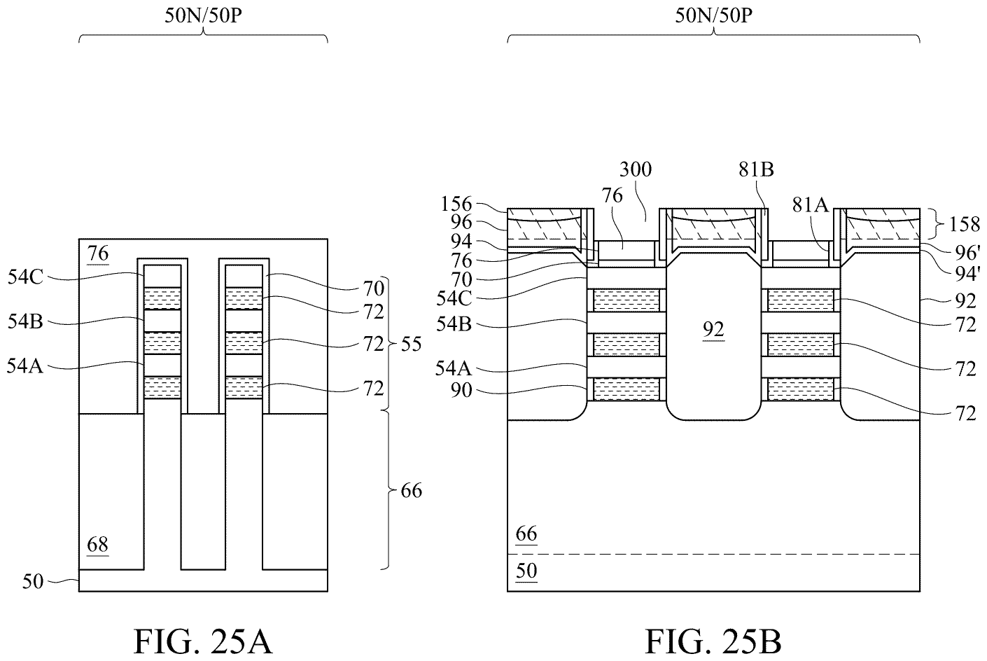

Then, the FIGS. 25A and 25B, the portions of the first gate spacers 81A in the recesses 300 are removed by a dry etch process. The etching process may use reaction gases that selectively etches the first gate spacers 811 at a faster rate than the hard mask 156. Removing the portions of the first gate spacers 81A may widen the recesses 300, reducing an aspect ratio of the recesses 30, and improve a manufacturing window of subsequent gate fill processes.

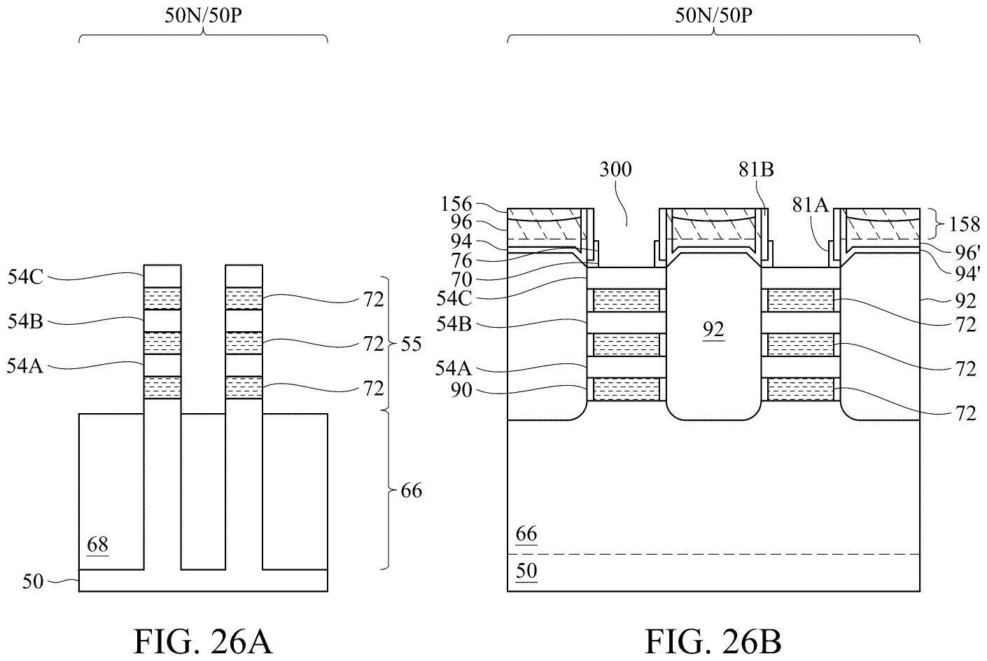

In FIGS. 26A and 26B, remaining portions of the dummy gates 76 are removed using a suitable etching process. The etching process may include a dry etch process using reaction gas(es) that selectively etch the dummy gates 76 at a faster rate than the hard mask 156, the first ILD 96, or the gate spacers 81. Each recess 300 exposes and/or overlies portions of nanostructures 55, which act as channel regions in subsequently completed nano-FETs. Portions of the nanostructures 55 which act as the channel regions are disposed between neighboring pairs of the epitaxial source/drain regions 92. During the removal, the dummy gate dielectrics 70 may be used as etch stop layers when the dummy gates 76 are etched. The dummy gate dielectrics 70 may then be removed after the removal of the dummy gates 76. The recesses 300 include widened upper regions, which advantageously improves a manufacturing window in subsequent fill processes.

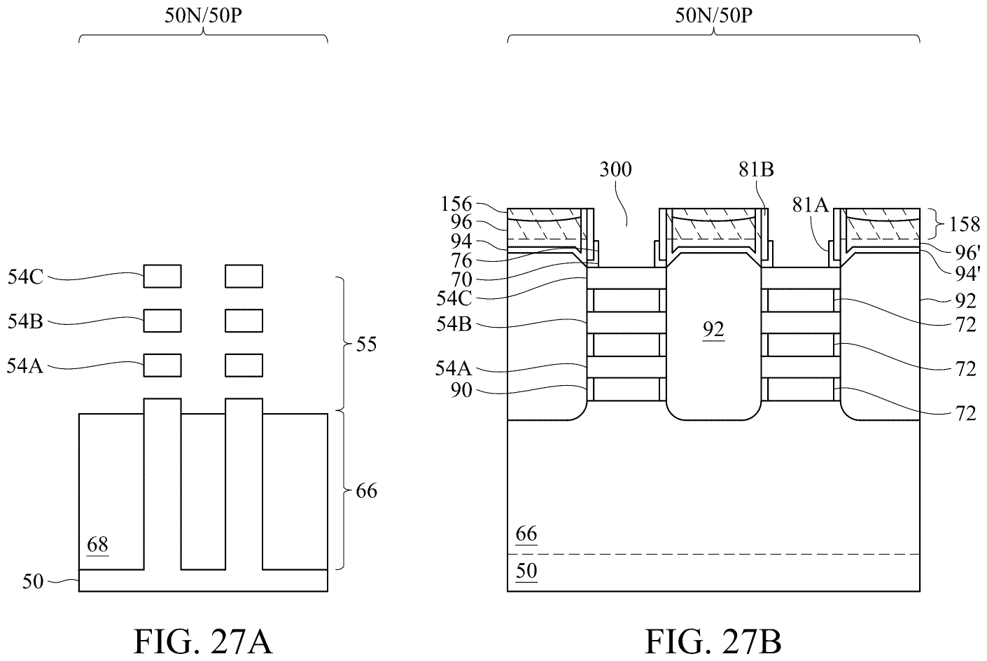

In FIGS. 27A and 27B the sacrificial material 72 is removed, extending the recesses 300. Removing the sacrificial material 72 may include performing an isotropic etching process such as wet etching or the like using etchants which are selective to the materials of the sacrificial material 72, while the second nanostructures 54 remain relatively unetched as compared to the sacrificial material 72. The sacrificial material 72 may be completely removed, or a residue of the sacrificial material 72 may remain on sidewalls of the inner spacers in the second recesses 98 (see e.g., FIG. 15C).

Removing the sacrificial material 72 may include an oxide etch process, such as a dry etch, a wet etch process using dHF as an etchant, or the like. The first ILD 96 may be protected from inadvertent etching by the implantation region 158, including the hard masks 156 and the upper portions 96U of the first ILD 96. As explained above, the implantation and annealing process 154 may reduce an etch rate of the hard masks 156 and the upper portions 96U to the oxide etch process compared to sacrificial material 72; fill any gaps around the hard masks 156 by expanding the hard masks 156; and improving a film quality of the hard masks 156 and the upper portions 96U of the first ILD 96. As a result, manufacturing defects can be reduced and yield can be improved.

FIGS. 28A-28C illustrates the completed device after additional processing similar to that described above in FIGS. 18A through 21C is performed where like reference numerals indicate like elements formed by like processes. In this embodiment, at least upper portions of the recesses 300 are widened by etching the first gate spacers 81A to reduce an aspect ratio of the recesses 300. As a result, the gate stack 100/102 may likewise have a wider upper portion than lower portion.

Various embodiments form a hard mask over an interlayer dielectric (ILD) to protect it during transistor fabrication. This ILD, situated between gate stacks and covering source/drain regions, is vulnerable to certain etching processes. To enhance the hard mask's effectiveness, embodiments include performing an ion implantation and annealing process. This treatment improves the hard mask's function in several ways. It enhances adhesion between the hard mask and surrounding features by causing expansion. The process also reduces the etching rate of both the hard mask and ILD during oxide etching steps. Additionally, it increases the density of these layers through impurity reduction. As a result, the quality and protective capacity of the hard mask improve, minimizing the risk of manufacturing defects such as unintended damage to the ILD or source/drain regions.

In some embodiments, a method includes depositing a first interlayer dielectric (ILD) surrounding a first dummy gate stack and a second dummy gate stack; recessing the first ILD below top surfaces of the first dummy gate stack and the second dummy gate stack; forming a hard mask over the first ILD and between the first dummy gate stack and the second dummy gate stack; performing an ion implantation process to implant dopants into the hard mask, wherein the ion implantation process reduces an etch rate of the hard mask to an oxide etch process; and after performing the ion implantation process, replacing the first dummy gate stack and the second dummy gate stack with first gate stack and a second gate stack. Optionally, the method further includes after performing the ion implantation process and prior to replacing the first dummy gate stack and the second dummy gate stack, performing a thermal anneal process on the hard mask and the first ILD. Optionally, the ion implantation process comprises implanting carbon, nitrogen, silicon, boron, or argon into the hard mask. Optionally, the ion implantation process is performed at an implantation energy in a range of 1 keV to 20 keV. Optionally, a dosage of the ion implantation process is at least 1E20 atoms/cm³. Optionally, the ion implantation process further implants dopants into an upper portion of the first ILD. Optionally, the ion implantation process reduces an etch rate of the upper portion of the first ILD to the oxide etch process.

In some embodiments, method includes forming a plurality of nanostructures comprising first nanostructures alternatingly stacked with second nanostructures; forming a dummy gate stack over and along sidewalls of the plurality of nanostructures; replacing the second nanostructures with a sacrificial material; depositing an interlayer dielectric (ILD) around the dummy gate stack; forming a hard mask over the ILD, the hard mask extending along a sidewall of the dummy gate stack; implanting dopants into the hard mask and at least an upper portion of the ILD; removing the dummy gate stack to form a recess; removing the sacrificial material using an etch process to extend the recess around the first nanostructures, wherein an etch rate of the hard mask and the upper portion of the ILD are lower than an etch rate of the sacrificial material during the etch process; and forming a gate stack in the recess. Optionally, the method further includes performing a thermal anneal between implanting the dopants and removing the sacrificial material. Optionally, the method further includes breaking vacuum between implanting dopants into the hard mask and performing the thermal anneal. Optionally, performing the thermal anneal increases a density of the hard mask and the upper portion of the ILD. Optionally, the sacrificial material is an oxide, and the etch process is a wet etch process using diluted hydrofluoric acid (dHF) as an etchant. Optionally, implanting the dopants comprises not implanting the dopants into a lower portion of the ILD, and wherein the etch rate of the upper portion of the ILD is greater than an etch rate of the lower portion of the ILD during the etch process. Optionally, a gap is disposed between the hard mask and the ILD prior to implanting the dopants into the hard mask, and wherein implanting the dopants into the hard mask expands the hard mask to fill the gap.

In some embodiments, a device includes a plurality of nanostructures extending between source/drain regions; a gate stack over and around the plurality of nanostructures; an interlayer dielectric (ILD) around the gate stack; and a hard mask over the interlayer dielectric, the hard mask extending along a sidewall of the gate stack, wherein an implantation region extends through the hard mask and into an upper portion of the ILD, and wherein a density of the upper portion of the ILD is higher than a density of a lower portion of the ILD. Optionally, the implantation region has a peak dopant concentration in the upper portion of the ILD. Optionally, the implantation region has a peak dopant concentration in the upper portion of the hard mask. Optionally, an etch rate of the upper portion of the ILD is lower than an etch rate of the lower portion of the ILD relative an oxide etch process. Optionally, the device further includes gate spacers along sidewalls of the gate stack, wherein the implantation region extends into an upper portion of the gate spacers. Optionally, the implantation region comprises carbon, nitrogen, silicon, boron, or argon dopants.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

1. A method comprising:
depositing a first interlayer dielectric (ILD) surrounding a first dummy gate stack and a second dummy gate stack;
recessing the first ILD below top surfaces of the first dummy gate stack and the second dummy gate stack;
forming a hard mask over the first ILD and between the first dummy gate stack and the second dummy gate stack;
performing an ion implantation process to implant dopants into the hard mask, wherein the ion implantation process reduces an etch rate of the hard mask to an oxide etch process; and
after performing the ion implantation process, replacing the first dummy gate stack and the second dummy gate stack with first gate stack and a second gate stack.

2. The method according to claim 1 further comprising:
after performing the ion implantation process and prior to replacing the first dummy gate stack and the second dummy gate stack, performing a thermal anneal process on the hard mask and the first ILD.

3. The method according to claim 1, wherein the ion implantation process comprises implanting carbon, nitrogen, silicon, boron, or argon into the hard mask.

4. The method according to claim 1, wherein the ion implantation process is performed at an implantation energy in a range of 1 keV to 20 keV.

5. The method according to claim 1, wherein a dosage of the ion implantation process is at least 1E20 atoms/cm³.

6. The method according to claim 1, wherein the ion implantation process further implants dopants into an upper portion of the first ILD.

7. The method according to claim 6, wherein the ion implantation process reduces an etch rate of the upper portion of the first ILD to the oxide etch process.

8. A method comprising:
forming a plurality of nanostructures comprising first nanostructures alternatingly stacked with second nanostructures;
forming a dummy gate stack over and along sidewalls of the plurality of nanostructures;
replacing the second nanostructures with a sacrificial material;
depositing an interlayer dielectric (ILD) around the dummy gate stack;
forming a hard mask over the ILD, the hard mask extending along a sidewall of the dummy gate stack;
implanting dopants into the hard mask and at least an upper portion of the ILD;
removing the dummy gate stack to form a recess;
removing the sacrificial material using an etch process to extend the recess around the first nanostructures, wherein an etch rate of the hard mask and the upper portion of the ILD are lower than an etch rate of the sacrificial material during the etch process; and
forming a gate stack in the recess.

9. The method of claim 8 further comprising performing a thermal anneal between implanting the dopants and removing the sacrificial material.

10. The method of claim 9, further comprising breaking vacuum between implanting the dopants into the hard mask and performing the thermal anneal.

11. The method of claim 9, wherein performing the thermal anneal increases a density of the hard mask and the upper portion of the ILD.

12. The method of claim 8, wherein the sacrificial material is an oxide, and the etch process is a wet etch process using diluted hydrofluoric acid (dHF) as an etchant.

13. The method of claim 8, implanting the dopants comprises not implanting the dopants into a lower portion of the ILD, and wherein the etch rate of the upper portion of the ILD is less than an etch rate of the lower portion of the ILD during the etch process.

14. The method of claim 8, wherein a gap is disposed between the hard mask and the ILD prior to implanting the dopants into the hard mask, and wherein implanting the dopants into the hard mask expands the hard mask to fill the gap.

15. A device comprising:
a plurality of nanostructures extending between source/drain regions;
a gate stack over and around the plurality of nanostructures;
an interlayer dielectric (ILD) around the gate stack; and
a hard mask over the interlayer dielectric, the hard mask extending along a sidewall of the gate stack, wherein an implantation region extends through the hard mask and into an upper portion of the ILD, and wherein a density of the upper portion of the ILD is higher than a density of a lower portion of the ILD.

16. The device of claim 15, wherein the implantation region has a peak dopant concentration in the upper portion of the ILD.

17. The device of claim 15, wherein the implantation region has a peak dopant concentration in an upper portion of the hard mask.

18. The device of claim 15, wherein an etch rate of the upper portion of the ILD is lower than an etch rate of the lower portion of the ILD relative an oxide etch process.

19. The device of claim 15, further comprising gate spacers along sidewalls of the gate stack, wherein the implantation region extends into an upper portion of the gate spacers.

20. The device of claim 16, wherein the implantation region comprises carbon, nitrogen, silicon, boron, or argon dopants.
